(19) United States
(12) Patent Application Publication
(10) Pub. No.: US 2019/0206287 A1
(43) Pub. Date: Jul. 4, 2019

(54) ORGANIC EL DISPLAY PANEL, ORGANIC EL DISPLAY DEVICE, AND METHOD FOR MANUFACTURING SAME

(71) Applicant: JOLED INC., Tokyo (JP)

(72) Inventors: Hideki KOBAYASHI, Tokyo (JP); Jiro YAMADA, Tokyo (JP); Kaoru ABE, Tokyo (JP); Kazuma TERAMOTO(deceased), Tokyo (JP); Kenichi NENDAI, Tokyo (JP)

(21) Appl. No.: 16/304,133

(22) PCT Filed: May 22, 2017
(86) PCT No.: PCT/JP2017/019003

§ 371 Date: Nov. 22, 2018

(30) Foreign Application Priority Data
May 24, 2016 (JP) 2016-103705

(51) Int. Cl. G09F 9/302; H01L 27/32; H01L 51/50; H05B 33/10; H05B 33/22

(52) U.S. Cl. CPC G09F 9/302; H01L 27/3244; H01L 51/5012; H01L 51/5072; H05B 33/22; H01L 51/5056; H05B 33/10

(57) ABSTRACT

An organic electroluminescence (EL) display panel includes pixels arranged in a matrix of rows and columns. The pixels each include a lower layer, an inner insulating layer, an application-type functional layer, and an upper electrode that are layered in this order. The lower layer includes a lower electrode. The functional layer includes a light-emitting layer. The inner insulating layer has one or more openings in which the lower layer is exposed. The openings each have a width increasing toward the upper electrode and have a slope toward a periphery of the pixel. In plan view, the openings are constituted from a plurality of elongated opening pieces.

### TECHNICAL FIELD

The present disclosure relates to organic electroluminescence (EL) display panels that use organic EL elements employing electroluminescence of organic material, and to organic EL display devices using the same.

### BACKGROUND ART

In recent years, lighting devices and organic EL display devices using organic EL elements as light emitting elements have become increasingly widespread. Further, there has been a demand for development in efficient light extraction art for such organic EL display devices. This is because an improvement in light extraction efficiency enables an effective use of light emission amount of organic EL elements, thereby contributing to power saving and service life prolonging.

One of methods of improving the light extraction efficiency is to provide organic EL display devices with reflectors (reflective structure), such as disclosed in Patent Literature 2.

### CITATION LIST

### Patent Literature

### [Patent Literature 1]

Japanese Patent Application Publication No. 2013-240733

### [Patent Literature 2]

Japanese Patent Application Publication No. 2013-191533

### SUMMARY

### Technical Problem

Meanwhile, one of methods of efficiently forming functional layers is to apply an ink containing functional materials with a wet process such as an ink jet method, such as disclosed in Patent Literature 1. In such functional layer formation with the wet process, the positional accuracy for layer formation does not depend on the substrate size. For this reason, the wet process is suitable for large-sized panel manufacturing and efficient panel manufacturing by cutting from large-sized substrates.

On the other hand, ink application with the wet process might result in an inappropriate ink spread depending on the structure immediately below functional layers. This is because the wet process does not intend to be used for ink application especially to regions having convex portions. Such an inappropriate ink spread causes ununiform film thickness of the functional layers, and thus might deteriorate luminous efficiency and panel service life.

The present disclosure aims to provide an organic EL display panel that has both reflectors and functional layers formed with the wet process, and maintains a high light extraction efficiency and a high uniformity in film thickness of the functional layers.

### Solution to Problem

One aspect of the present disclosure provides an organic electroluminescence (EL) display panel including pixels arranged in a matrix of rows and columns, wherein the pixels each include a lower layer, an inner insulating layer, an application-type functional layer, and an upper electrode that are layered in this order, the lower layer including a lower electrode, the functional layer including a light-emitting layer, the inner insulating layer has one or more openings in which the lower layer is exposed, the openings each have a width increasing toward the upper electrode and have a slope toward a periphery of the pixel, and in plan view, the openings are constituted from a plurality of elongated opening pieces.

### Advantageous Effects

According to the organic EL display panel relating to the one aspect of the present disclosure, one or more reflectors (openings) are constituted from elongated opening pieces. This configuration maintains a high light extraction efficiency exhibited by the reflectors. Further, the application-type functional layers are each elongated. This configuration maintains a high flow of an ink containing functional layer materials and a high uniformity in film thickness of the functional layers, thereby improving the luminous efficiency and the panel service life.

### BRIEF DESCRIPTION OF DRAWINGS

FIG. 1 is a schematic block diagram of circuit configuration of an organic EL display device 1 relating to an embodiment of the present disclosure.

FIG. 2 is a schematic circuit diagram of circuit configuration of each subpixel 100se of an organic EL display panel 10 used in the organic EL display device 1.

FIG. 3 is a schematic plan view of part of the organic EL display panel 10.

FIGS. 4A and 4B are enlarged plan views of a portion X1 in FIG. 3, where FIG. 4A shows one pixel 100 of the organic EL display panel 10, and FIG. 4B shows subpixels 100a constituting the pixel 100.

FIG. 5 is a schematic cross-sectional view taken along a line A1-A1 in FIG. 4B.

FIG. 6 is a schematic cross-sectional view taken along a line A2-A2 in FIG. 4B.

FIG. 7 is a schematic cross-sectional view taken along a line B-B in FIG. 4B.

FIGS. 8A to 8E are schematic cross-sectional views of the organic EL display panel 10 during manufacture, taken along a line at the same position as the line A1-A1 in FIG. 4B, where FIG. 8A shows a formation process of a substrate 100x, FIG. 8B shows a formation process of passivation layers 116, FIG. 8C shows a formation process of contact holes 116a, FIG. 8D shows a formation process of an interlayer insulating layer 118, and FIG. 8E shows a formation process of pixel electrode layers 119.

FIGS. 9A to 9C are schematic cross-sectional views of the organic EL display panel 10 during manufacture, taken along the line at the same position as the line A1-A1 in FIG. 4B, each showing a formation process of an insulating layer 122.

FIGS. 10A to 10C are schematic cross-sectional views of the organic EL display panel 10 during manufacture, taken along the line at the same position as the line A1-A1 in FIG. 4B, where FIG. 10A shows a formation process of a hole injection layer 120 and a hole transport layer 121, FIG. 10B shows a formation process of light emitting layers 123, and FIG. 10C shows a formation process of an electron transport layer 124, a counter electrode layer 125, and a sealing layer 126.

FIGS. 11A and 11B are schematic cross-sectional views of the organic EL display panel 10 during manufacture, taken along the line at the same position as the line A1-A1 in FIG. 4B, where FIG. 11A shows a formation process of a bond layer 127 and FIG. 11B shows a bond process of a CF substrate 131.

FIGS. 12A to 12D are schematic cross-sectional views of the organic EL display panel 10 during manufacture, taken along a line at the same position as the line B-B in FIG. 4B, where FIGS. 12A to 12D each show the formation process of the insulating layer 122.

FIGS. 13A to 13D are schematic cross-sectional views of the organic EL display panel 10 during manufacture, taken along the line at the same position as the line B-B in FIG. 4B, where FIG. 13A shows the formation process of the hole injection layer 120 and the hole transport layer 121, FIGS. 13B and 13C each shows the formation process of the light emitting layers 123, and FIG. 13D shows the formation process of the electron transport layer 124, the counter electrode layer 125, and the sealing layer 126.

FIGS. 14A and 14B show processes of applying inks for light emitting layer formation to substrates in the organic EL display panel 10 during manufacture, where FIG. 14A shows application for lattice-shaped banks, and FIG. 14B shows application for line-shaped banks.

FIGS. 15A and 15B are schematic cross-sectional views of the organic EL display panel 10 during manufacture, taken along the line at the same position as the line B-B in FIG. 4B, where FIG. 15A shows the formation process of the bond layer 127, and FIG. 15B shows the bond process of the CF substrate 131.

FIGS. 16A to 16F are schematic cross-sectional views of the organic EL display panel 10 during manufacture, showing manufacturing of the CF substrate 131.

FIGS. 17A to 17I are plan views of part of the insulating layer 122 in one subpixel 100se relating to the embodiment.

FIG. 18 shows the shape of openings of the insulating layer 122, the spread of inks for functional layer formation, and the light extraction efficiency by reflectors in subpixels 100se relating to the embodiment and modifications.

FIGS. 19A and 19B are partial external views of part of the insulating layer 122 in one subpixel 100se relating to the embodiment.

### DESCRIPTION OF EMBODIMENTS

<<Process by which One Aspect of the Present Disclosure was Achieved>>

To improve the light extraction efficiency, organic EL display devices are provided with reflectors (reflective structure) such as disclosed in Patent Literature 2. According to such an organic EL display panel of Patent Literature 2, subpixels constituting pixels each have one reflector. To further improve effects of the reflectors, the study has been promoted on a configuration in which such subpixels each have a plurality of reflectors. In this reflector configuration, a plurality of micropixels each having one reflector are formed in each subpixel that includes a pixel inner insulating layer sandwiched between a lower electrode and a functional layer.

Meanwhile, layer formation with the wet process has been performed for functional layers such as light emitting layers, carrier injection layers, and carrier transport layers, especially with respect to large-sized panels, as disclosed for example in Patent Literature 1. However, such functional layer formation with the wet process requires a uniform ink spread over the entire subpixels. According to conventional wet processes, functional layers are formed by spreading an ink over a single depression in a functional layer formation region of each subpixel. In other words, the conventional wet processes do not intend to be used for applying an ink over a plurality of depressions of each subpixel. An inappropriate ink spread causes an ununiform film thickness of functional layers between micropixels in each subpixel, and causes dark spots where no light is emitted due to functional layers insufficiently formed in micropixels. As a result, the luminance and the panel service life might deteriorate.

In view of this, the inventors considered the shape of reflectors according to which an improved light extraction efficiency is exhibited while an ink spread is improved for high luminous efficiency and service life of pixels.

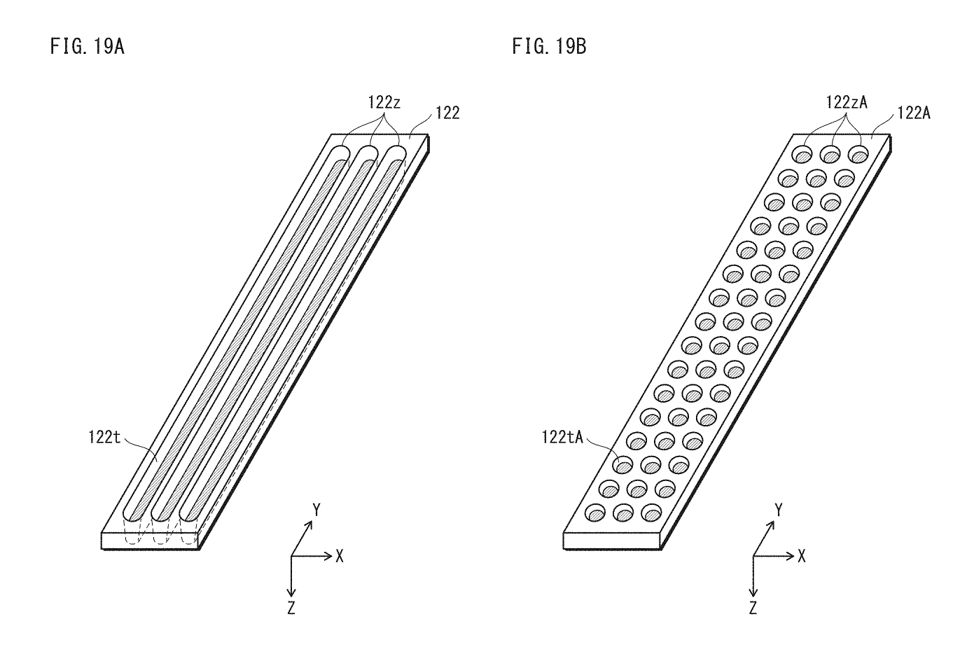

When refractive indices of a light emission side (for example, a bond layer) and a light emitting element side (for example, an insulating layer) of a reflector are represented by n₁ and n₂, respectively, the following relationships should preferably be satisfied: 1.1≤n₁≤1.8 (Formula 1); and |n₁−n₂|≥0.20 (Formula 2). Also, when a gradient of slopes of the reflectors is represented by θ, the following relationships should preferably be satisfied: n₂<n₁ (Formula 3); and 75.2−54(n₁−n₂)≤θ≤81.0−20(n₁−n₂) (Formula 4). For example, when n₁−n₂ is approximately 0.2 to 0.4, the reflectors should preferably have slopes with a gradient of approximately 72°. This is because light emitted from micropixels enters the reflectors from the light emission side, and then is reflected toward the light emission side due to total reflection in the reflectors. Thus, the reflectors should preferably be frustums, and should preferably have circular or regular polygonal bottom surfaces. Since the shape of the reflectors is defined by the shape of the pixel inner insulating layers, the pixel inner insulating layers should preferably be arranged in a grid pattern where truncated conical openings are arranged at equal intervals both in the column direction and the row direction such as shown in FIG. 19B. However, the inventors' study proved that an ink containing functional layer materials insufficiently spreads over such inner insulating layers, and thus a large amount of the ink is necessary for application over the entire pixels compared with pixels including no inner insulating layer. Then, the inventors achieved one aspect of the present disclosure as a result of consideration of reflectors according to which the light extraction efficiency and the ink spread are improved.

### Aspects of the Present Disclosure

One aspect of the present disclosure provides an organic electroluminescence (EL) display panel including pixels arranged in a matrix of rows and columns, wherein the pixels each include a lower layer, an inner insulating layer, an application-type functional layer, and an upper electrode that are layered in this order, the lower layer including a lower electrode, the functional layer including a light-emitting layer, the inner insulating layer has one or more openings in which the lower layer is exposed, the openings each have a width increasing toward the upper electrode and have a slope toward a periphery of the pixel, and in plan view, the openings are constituted from a plurality of elongated opening pieces.

According to the organic EL display panel relating to the one aspect of the present disclosure, the reflectors (openings) are constituted from elongated opening pieces. This configuration maintains a high light extraction efficiency exhibited by the reflectors. Further, the application-type functional layers are each elongated. This configuration maintains a high flow of an ink containing functional layer materials and a high uniformity in film thickness of the functional layers, thereby improving the luminous efficiency and the panel service life.

Also, in another aspect, in plan view, the plurality of opening pieces may include opening pieces that are arranged in a row direction and extend in a column direction.

Also, in another aspect, in plan view, in plan view, the plurality of opening pieces may further include opening pieces that are arranged in the column direction and extend in the column direction.

According to these other aspects, it is possible to maintain a high ink flow especially in the column direction and a high uniformity in film thickness of the functional layers.

Also, in another aspect, in plan view, the plurality of opening pieces may include opening pieces that are arranged in a column direction and extend in a row direction.

Also, in another aspect, in plan view, the plurality of opening pieces may further include opening pieces that are arranged in the row direction and extend in the row direction.

According to these other aspects, it is possible to maintain a high ink flow especially in the row direction and a high uniformity in film thickness of the functional layers.

Also, in another aspect, in plan view, the plurality of opening pieces may include opening pieces that extend in a column direction and one or more opening pieces that extend in a row direction, and in plan view, the opening pieces extending in the column direction may each partially overlap with one or more of the opening pieces extending in the row direction.

Also, in another aspect, in plan view, the plurality of opening pieces may include opening pieces that extend in a row direction and one or more opening pieces that extend in a column direction, and in plan view, the opening pieces extending in the row direction may each partially overlap with one or more of the opening pieces extending in the column direction.

According to these other aspects, it is possible to maintain a high ink flow especially in each pixel and a high uniformity in film thickness of the functional layers.

One aspect of the present disclosure provides an organic electroluminescence (EL) display device comprising the organic EL display panel of one of the above aspects.

One aspect of the present disclosure provides a method of manufacturing an organic electroluminescence (EL) display panel including pixels arranged in a matrix of rows and columns, the method comprising: preparing a substrate; forming pixel electrode layers on the substrate in the matrix, the pixel electrode layers being made of a light-reflective material; forming an insulating layer above the substrate and the pixel electrode layers; providing one or more openings for each of the pixels in the insulating layer by a photolithography method, the pixel electrode layers being exposed in the openings, the openings each having a width increasing toward the upper electrode and have a slope toward a periphery of the pixel, and the openings being constituted from a plurality of elongated opening pieces in plan view; forming, at least in the openings of the pixels, functional layers including light emitting layers by applying an ink above the pixel electrode layers and drying the ink, the ink containing a material of the light emitting layers; and forming a light-transmissive counter electrode layer above the functional layers. With this configuration, it is possible to manufacture the organic electroluminescence (EL) display panel relating to the one aspect of the present disclosure.

### EMBODIMENT

1 Circuit Configuration

1.1 Circuit Configuration of Display Device 1

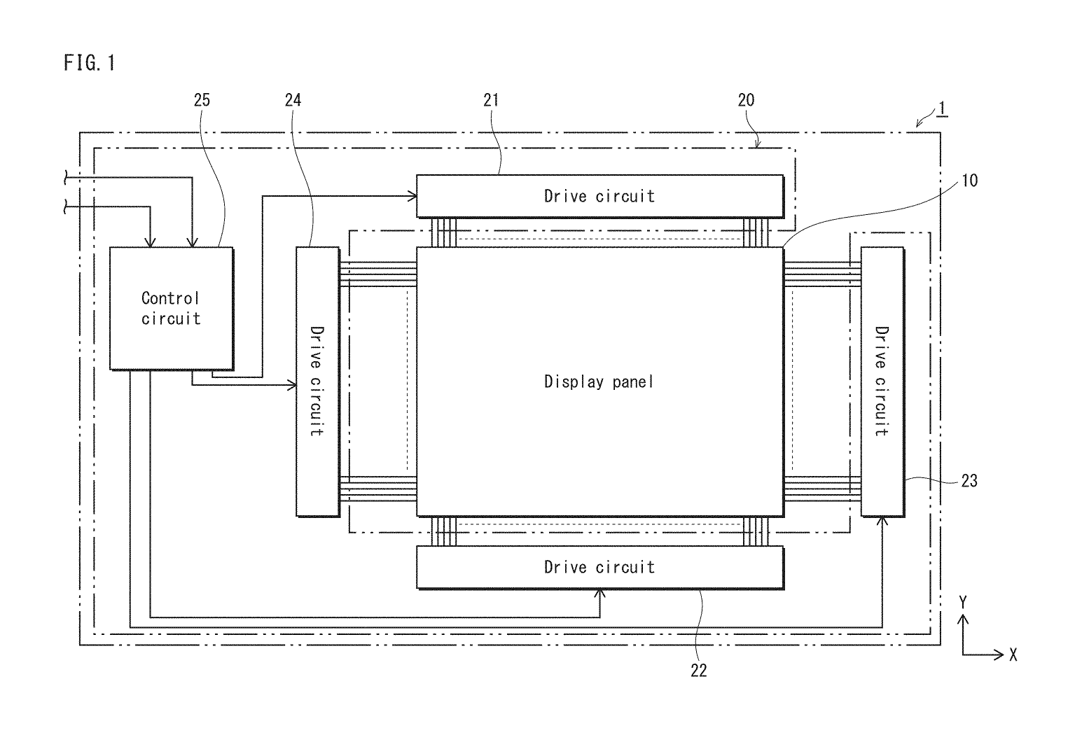

The following describes circuit configuration of an organic EL display device 1 (hereinafter referred to just as display device 1) relating to an embodiment, with reference to FIG. 1.

As shown in FIG. 1, the display device 1 includes an organic EL display panel 10 (hereinafter referred to just as display panel 10) and a drive control circuit unit 20 connected thereto.

The display panel 10 is an organic EL panel that makes use of electroluminescence of organic material, in which organic EL elements are arranged in a matrix, for example. The drive control circuit unit 20 includes four drive circuits 21-24 and a control circuit 25.

The arrangement of the circuits of the drive control circuit unit 20 with respect to the display panel 10 in the display device 1 is not limited to the configuration shown in FIG. 1.

1.2 Circuit Configuration of Display Panel 10

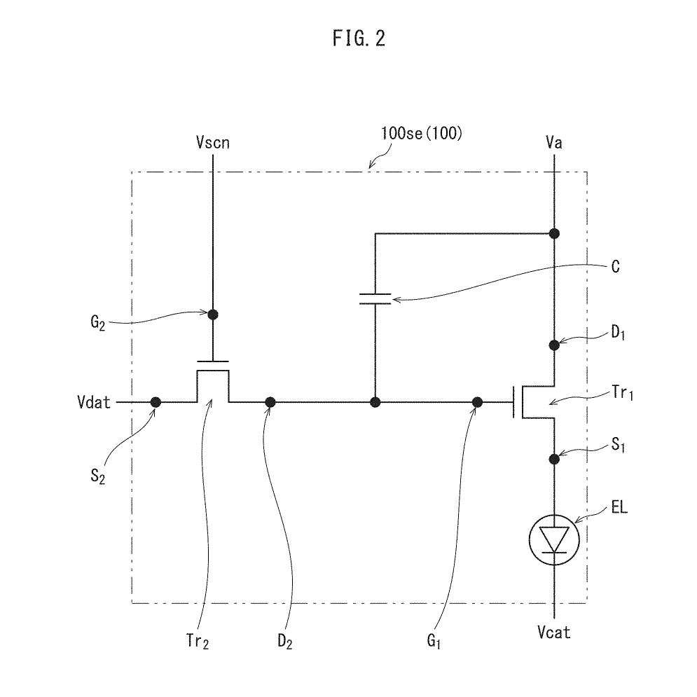

The display panel 10 includes a plurality organic EL elements that are composed of three-color subpixels (not shown) emitting light of red (R), green (G), and blue (B) colors. Circuit configuration of the subpixels 100se is described with reference to FIG. 2.

FIG. 2 is a schematic circuit diagram showing the circuit configuration of an organic EL element 100 corresponding to the subpixels 100se of the display panel 10 used in the display device 1. The organic EL display elements 100 constituting the unit pixels 100e are arranged in a matrix as a display region of the display panel 10.

In the display panel 10 relating to the present embodiment, as shown in FIG. 2, each subpixel 100se includes two transistors Tr₁ and Tr₂, a single capacitance C, and an organic EL element unit EL as a light emitting unit. The transistor Tr₁ is a drive transistor, and the transistor Tr₂ is a switching transistor.

A gate G₂ and a source S₂ of the switching transistor Tr₂ are respectively connected to a scanning line Vscn and a data line Vdat. A drain D₂ of the switching transistor Tr₂ is connected to a gate G₁ of the drive transistor Tr₁.

A drain D₁ and a source S₁ of the drive transistor Tr₁ are respectively connected to a power line Va and a pixel electrode layer (anode) of the organic EL element unit EL. A counter electrode layer (cathode) of the organic EL element unit EL is connected to a ground line Vcat.

Note that the capacitance C is provided so as to connect between the drain D₂ of the switching transistor Tr₂ and the power line Va and connect between the gate G₁ of the drive transistor Tr₁ and the power line Va.

In the display panel 10, one unit pixel 100e is composed of a combination of adjacent subpixels 100se (for example, three subpixels 100se of R, G, and B luminescent colors), and a pixel region is composed of the subpixels 100se that are distributed. A gate line GL is extracted from the gate G₂ of each subpixel 100se, and is connected to the scanning line Vscn that is connected to the outside of the display panel 10. Similarly, a source line SL is extracted from the source S₂ of each subpixel 100se, and is connected to the data line Vdat that is connected to the outside of the display panel 10.

Furthermore, the power line Va and the ground line Vcat of each subpixel 100se are collectively connected to the power line Va and the ground line Vcat.

3. Overall Configuration of Organic EL Display Panel 10

The following describes the display panel 10 relating to the present embodiment with reference to the drawings. Note that the drawings are pattern diagrams and are not necessarily drawn to scale.

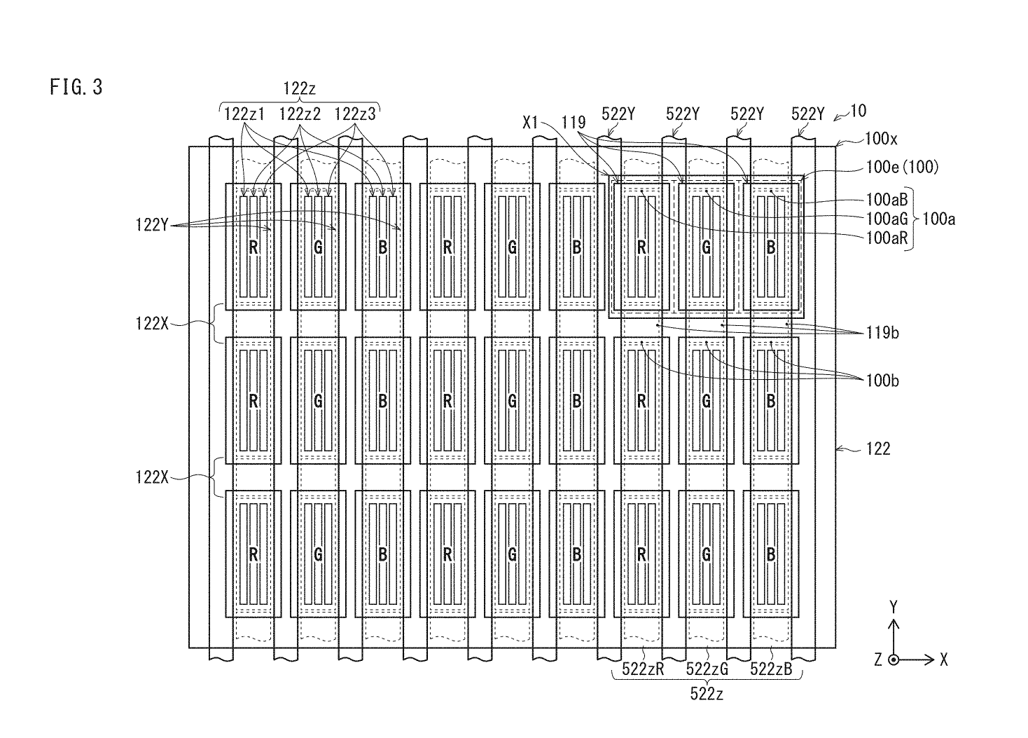

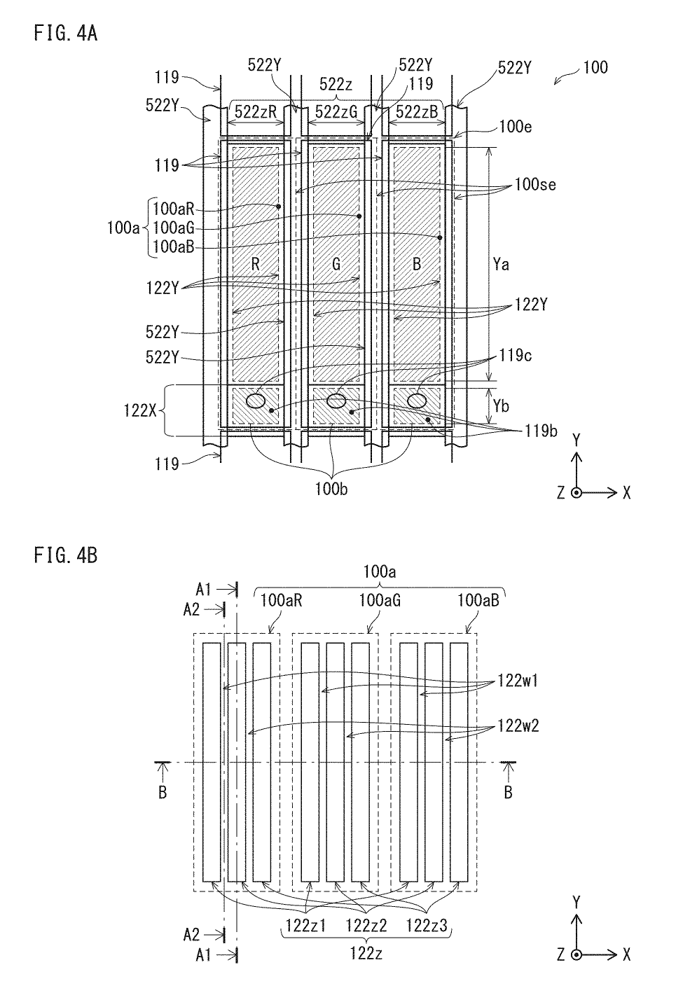

FIG. 3 is a schematic plan view of part of the display panel 10 relating to the present embodiment. FIG. 4A is an enlarged plan view of a portion X1 in FIG. 3 indicating one pixel 100 of the display panel 10. FIG. 4B is an enlarged plan view of subpixels 100a of the pixel 100.

The display panel 10 is an organic EL display panel that makes use of electroluminescence of organic compound. In the display panel 10, the organic EL elements 100 each constituting a pixel are arranged in a matrix on a substrate 100x (thin film transistor (TFT) substrate) on which TFTs are formed. The display panel 10 is of the top-emission type and emits light from an upper surface thereof. As shown in FIG. 3, the display panel 10 includes the organic EL elements 100, constituting the pixels, arranged in a matrix. Here, the X-direction, the Y-direction, and the Z-direction in FIG. 3 are respectively referred to as the row direction, the column direction, and the thickness direction in the display panel 10 in the present specification.

As shown in FIG. 3, the display panel 10 includes pixel electrode layers 119 that are arranged on the substrate 100x in a matrix, and includes an insulating layer 122 that covers the pixel electrode layers 119.

In the case where the insulating layer 122 has an upper limit film thickness of 10 μm or less, it is possible to perform shape control at the manufacturing in terms of variation in film thickness and control on bottom line thickness. Furthermore, in the case where the insulating layer 122 has an upper limit film thickness of 7 μm or less, it is possible to suppress an increase in operation process caused by an increase in exposure period during the exposure process, thereby to suppress a decrease in productivity during the mass production process. Also, the insulating layer 122 needs to have the film thickness and the bottom line thickness such that as the film thickness decreases, a difference therebetween decreases to substantially zero. The lower limit film thickness of the insulating layer 122 is determined in accordance with the resolution limit of materials and exposure machines. The insulating layer 122 having a lower limit film thickness of 1 μm or more can be manufactured with use of a semiconductor stepper. The insulating layer 122 having a lower limit film thickness of 2 μm or more can be manufactured with use of a stepper or scanner for flat panels. In view of the above, the insulating layer 122 should preferably have a film thickness of 1 μm to 10 μm, and more preferably a film thickness of 2 μm to 7 μm, for example. In the present embodiment, the insulating layer 122 has a film thickness of approximate 5.0 μm. The pixel electrode layers 119 are rectangular in plan view, and are made of a light-reflective material. The pixel electrode layers 119, which are arranged in a matrix, each correspond to any one of three subpixels 100aR, 100aG, and 100aB that are arranged in the row direction in this order (hereinafter referred to collectively as subpixels 100a when no distinction is made therebetween).

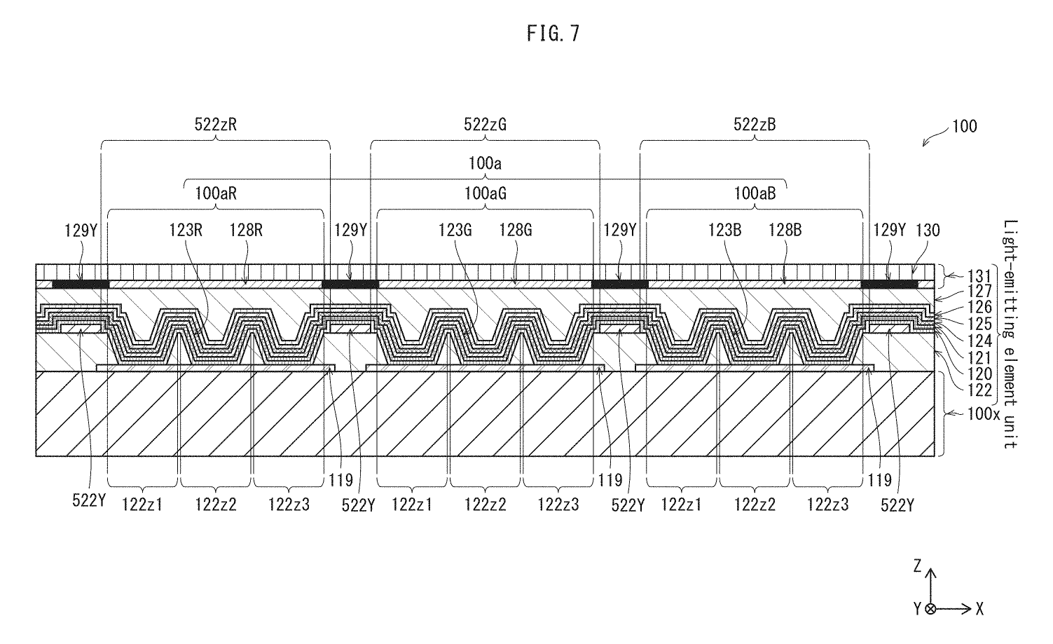

The insulating layer 122 is layered above the pixel electrode layers 119 which are arranged in a matrix. Above each of the pixel electrode layers 119, the insulating layer 122 has three elongated openings 122z1, 122z2, and 122z3. As shown in FIG. 7, the openings each have a trapezoidal cross section taken along a transverse direction whose width increases toward the upper surface of the insulating layer 122. When a depth, an upper width in the row direction, and a lower width in the row direction in the cross section of the openings are represented by D, Wₕ, and W₁, respectively, the following relationships should preferably be satisfied:

0.5≤W₁/Wₕ≤0.8 (Formula 5)

0.5≤D/W₁≤2.0 (Formula 6).

Also, a gradient R formed by walls of the openings is determined by the following relationship:

R=(Wₕ−W₁/2D (Formula 7).

A rectangular region surrounded by outer edges of the openings 122z1, 122z2, and 122z3 in the row direction and column direction constitutes a luminous region 100a where light is emitted by organic compound. Here, among gaps between the luminous regions 100a, gaps in the row direction between the luminous regions 100a arranged in the column direction are referred to as insulating sublayers 122X, and gaps in the column direction between the luminous regions 100a arranged in the row direction are referred to as insulating sublayers 122Y. Accordingly, outer edges of the luminous regions 100a in the row direction are defined by outer edges of the insulating sublayers 122X in the row direction, and outer edges of the luminous regions 100a in the column direction are defined by outer edges of the insulating sublayers 122Y in the column direction. Hereinafter, outer edges in the row direction and outer edges in the column direction are respectively referred to simply as row outer edges and column outer edges.

The insulating sublayers 122X extending in the row direction (the X-direction in FIG. 3) are each arranged in the column direction above the column outer edges of two pixel electrode layers 119 that are adjacent to each other in the column direction and above a region adjacent to the column outer edges. A region where the insulating sublayer 122X is formed is a non-luminous region 100b. As shown in FIG. 3, the display panel 10 includes the luminous regions 100a and the non-luminous regions 100b that alternate in the column direction. In each of the non-luminous regions 100b, the pixel electrode layer 119 has a contact region 119b (contact window) for electrical connection via a connection electrode layer 117.

The display panel 10 includes banks that are arranged in lines. Column banks 522Y extending in the column direction (the Y-direction in FIG. 3) are arranged in the row direction above the insulating sublayers 122Y, such that each of the column banks 522Y is arranged above the row outer edges of two pixel electrode layers 119 that are adjacent to each other in the row direction and above a region adjacent to the row outer edges.

Each two adjacent column banks 522Y have a gap 522z therebetween, and accordingly the display panel 10 includes a large number of alternating column banks 522Y and gaps 522z.

The display panel 10 has three types of luminous regions 100a, namely luminous regions 100aR, 100aG, and 100aB that respectively emit red light, green light, and blue light (hereinafter referred to collectively as luminous regions 100a when no distinction is made therebetween). The gaps 522z include red gaps 522zR, green gaps 522zG, and blue gaps 522zB that respectively correspond to the luminous regions 100aR, 100aG, and 100aB (hereinafter referred to collectively as gaps 522z when no distinction is made therebetween). One set of the luminous regions 100aR, 100aG, and 100aB, which correspond to respective three subpixels 100se arranged in the row direction, constitutes a unit pixel 100e for color display.

Column light shielding sublayers 129Y are provided above the pixel electrode layers 119 so as to overlap row outer edges of the pixel electrode layers 119. Also, row light shielding sublayers 129X are provided above the pixel electrode layers 119 so as to overlap column outer edges of the pixel electrode layers 119 and so as not to partially overlap the contact regions 119b.

4. Configuration of Components of Display Panel 10

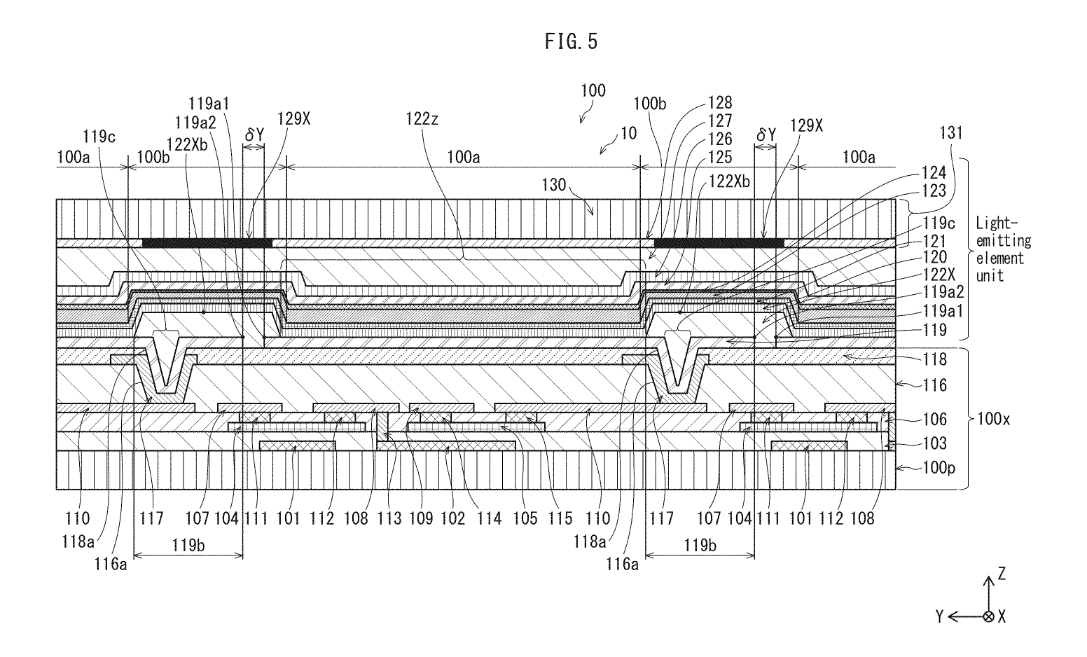

The following describes the configuration of the organic EL elements 100 of the display panel 10 with reference to schematic cross-sectional views in FIGS. 5 to 7. FIGS. 5 to 7 are schematic cross-sectional views respectively taken along a line A1-A1, a line A2-A2, and a line B-B in FIG. 4B.

The display panel 10 relating to the present embodiment is of an organic EL display panel of the top-emission type, and includes the substrate 100x (TFT substrate) on which the TFTs are formed in a lower part in the Z-axis direction and the organic EL element units are formed thereon.

4.1 Substrate 100x (TFT Substrate)

As shown in FIG. 5, gate electrodes 101 and 102 are formed with an interval therebetween on a lower substrate 100p, and a gate insulating layer 103 is formed so as to cover respective surfaces of the gate electrodes 101 and 102 and the lower substrate 100p. Channel layers 104 and 105 are formed on the gate insulating layer 103 so as to respectively correspond to the gate electrodes 101 and 102. A channel protection layer 106 is formed so as to cover respective surfaces of the channel layers 104 and 105 and the gate insulating layer 103.

Source electrodes 107 and drain electrodes 108 are formed with an interval therebetween on the channel protection layer 106 so as to correspond to the gate electrodes 101 and the channel layers 104. Similarly, source electrodes 110 and drain electrodes 109 are formed with an interval therebetween on the channel protection layer 106 so as to correspond to the gate electrode 102 and the channel layer 105.

Source lower electrodes 111 and 115 are respectively formed below the source electrodes 107 and 110 by being inserted through the channel protection layer 106. Drain lower electrodes 112 and 114 are respectively formed below the drain electrodes 108 and 109 by being inserted through the channel protection layer 106. The source lower electrodes 111 and the drain lower electrodes 112 have low portions in the Z-axis direction that are in contact with the channel layer 104. The drain lower electrodes 114 and the source lower electrodes 115 have low portions in the Z-axis direction that are in contact with the channel layer 105.

Also, the drain electrodes 108 are connected with the gate electrodes 102 via contact plugs 113 that are provided by being inserted through the gate insulating layer 103 and the channel protection layer 106.

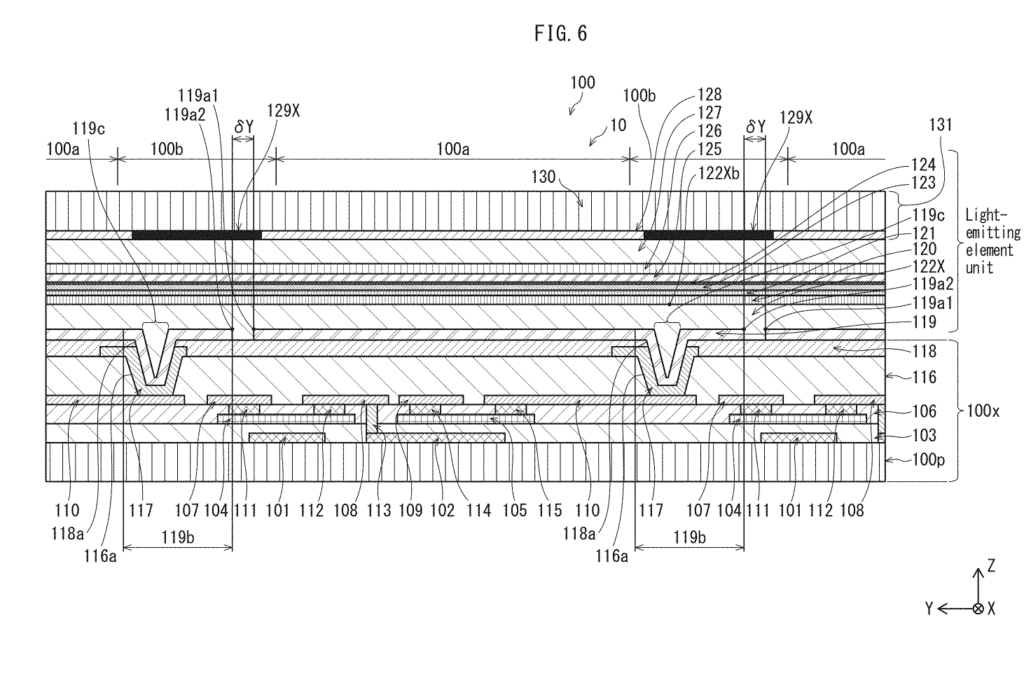

Note that the gate electrodes 101, the source electrodes 107, and the drain electrodes 108 respectively correspond to the gate G₂, the source S₂, and the drain D₂ in FIG. 2. Similarly, the gate electrodes 102, the source electrodes 110, and the drain electrodes 109 respectively correspond to the gate G₁, the source S₁, and the drain D₁ in FIG. 2. Accordingly, the switching transistor Tr₂ and the drive transistor Tr₁ are respectively formed leftward and rightward in the Y-axis direction in FIG. 6.

Note that the above configuration is just an example, and the arrangement of the transistors Tr₁ and Tr₂ is not limited to that in FIG. 5 and any configuration may be employed such as top-gate, bottom-gate, channel-etch, and etch-stop.

Passivation layers 116 are formed so as to cover the respective surfaces of the source electrodes 107 and 110, the drain electrodes 108 and 109, and the channel protection layer 106. The passivation layers 116 have contact holes 116a above part of upper portions of the source electrodes 110. The connection electrode layers 117 are layered so as to be along side walls of the contact holes 116a.

The connection electrode layers 117 have lower portions in the Z-axis direction that are connected with the source electrodes 110, and also have upper portions that are partially on the passivation layers 116. An interlayer insulating layer 118 is layered so as to cover respective surfaces of the connection electrode layers 117 and the passivation layers 116.

4.2 Organic EL Element Unit

(1) Pixel Electrode Layers 119

The pixel electrode layers 119 are formed in units of subpixels on the interlayer insulating layer 118. The pixel electrode layers 119 are provided for supplying carries to the light emitting layers 123. When functioning as anodes for example, the pixel electrode layers 119 supply holes to the light emitting layers 123. Also, since the display panel 10 is of the top-emission type, the pixel electrode layers 119 are light-reflective. The pixel electrode layers 119 are rectangular and plate-like. The pixel electrode layers 119 are arranged on the substrate 100x with intervals 6X therebetween in the row direction and with intervals 6Y therebetween in the column direction in the gaps 522z. Furthermore, the pixel electrode layers 119 have the connection concave parts 119c that are connected with the connection electrode layers 117 through contact holes 118a that are provided above the connection electrode layers 117 in the inter insulating layer 118. Accordingly, the pixel electrode layers 119 are each connected with the source S₁ of the TFT via the connection electrode layer 117. The connection concave parts 119c of the electrode layers 119 are concave toward the substrate 100x.

The pixel electrode layers 119 have column outer edges 119a1 and 119a2, and the connection concave parts 119c are provided on the side of the column outer edges 119a2. The contact regions 119b are ranges from the column outer edges 119a2 to regions including the connection concave parts 119c.

(2) Insulating Layer 122

The insulating layer 122 is made of an insulating material, and is formed so as to cover at least end edges of the pixel electrode layers 119 which are arranged in a matrix.

Above each of the pixel electrode layers 119 except the contact regions 119b, the insulating layer 122 has the elongated openings 122z. As shown in FIG. 7, in the openings 122z1, 122z2, and 122z3, the insulating layer 122 is not located on upper surfaces of the pixel electrode layers 119. The pixel electrode layers 119 are exposed in these openings so as to be in contact with a hole injection layer 120, which is described later. This configuration allows electrical charge supply in these openings from the pixel electrode layers 119 to the hole injection layer 120. Accordingly, the minimum rectangular region including the openings 122z1, 122z2, and 122z3 is the luminous region 100a where light is emitted by organic compound of any of the R, G, and B colors. Also, a gap of the insulating layer 122 between each two luminous regions 100a which are arranged in the column direction is the non-luminous region 100b. The insulating layer 122 has a bar 122w1, which is provided between each pair of the openings 122z1 and 122z2, and has a bar 122w2, which is provided between each pair of the openings 122z2 and 122z3.

Also, the insulating layer 122 includes the insulating sublayers 122Y, which are gaps between luminous regions 100a extending in the column direction and arranged in the row direction. Accordingly, the insulating sublayers 122Y define the row outer edges of the luminous regions 100a in the subpixels 100se. The insulating sublayers 122Y and the bars 122w1 and 122w2 each have a trapezoidal cross section taken along the row direction whose width decreases upward. With this configuration, the light emitting layers 123 efficiently emit light upward.

Also, the insulating layer 122 includes the insulating sublayers 122X (corresponding to the non-luminous regions 100b), which are gaps between luminous regions 100a extending in the row direction and arranged in the column direction. As shown in FIG. 4A, the insulating sublayers 122X are arranged above the contact regions 119b of the pixel electrode layers 119 and above the column outer edges 119a1 and 119a2 of the pixel electrode layers 119 which are adjacent to each other in the column direction. The insulating sublayers 122X cover the column outer edges 119a1 and 119a2 of the pixel electrode layers 119 thereby to prevent electric leakage between the pixel electrode layers 119 and the counter electrode layer 125, and thereby to define the column outer edges of the luminous regions 100a in the subpixels 100se.

(3) Column Banks 522Y

The column banks 522Y, extending in the column direction, are arranged in the row direction above the insulating sublayers 122Y. The column banks 522Y define the row outer edges of the light emitting layers 123, which are formed by stemming the flow in the row direction of the ink containing organic compound as the material of the light emitting layers 123. The column banks 522Y are each provided above a pair of the row outer edges 119a3 and 119a4 of two adjacent pixel electrode layers 119 so as to partially overlap the pixel electrode layers 119. The column banks 522Y are linear and each have a forward-tapered trapezoidal cross section taken along the row direction whose width decreases upwards. The column banks 522Y are provided in the column direction so as to be perpendicular to the insulating sublayers 122X, and have upper surfaces that are higher in position than the upper surfaces 122xb of the insulating sublayers 122X.

(4) Hole Injection Layer 120 and Hole Transport Layer 121

A hole injection layer 120 and a hole transport layer 121 are layered in this order on the column banks 522Y and on the pixel electrode layers 119 in the openings 122z. The hole transport layer 121 is in contact with the hole injection layer 120. The hole injection layer 120 and the hole transport layer 121 have a function of transporting holes, which are injected from the pixel electrode layers 119, to the light emitting layers 123.

(5) Light Emitting Layers 123

The display panel 10 includes a large number of alternating column banks 522Y and gaps 522z. The light emitting layers 123 extend in the column direction on an upper surface of the hole transport layer 121 in the gaps 522z which are defined by the column banks 522Y. The light emitting layer 123 emitting light of the R, G, and B colors are formed respectively in the red gaps 522zR, the green gaps 522zG, and the blue gaps 522zB, which respectively correspond to the luminous regions 100aR, 100aG, and 100aB.

The light emitting layers 123 are made of organic compound, and have a function of emitting light through recombination of holes and electrons thereinside. In the gaps 522z, the light emitting layers 123 are provided so as to be linear and extend in the column direction.

Light is emitted from only parts of the light emitting layers 123 to which carriers are supplied from the pixel electrode layers 119, and accordingly no electroluminescence of organic compound occurs in regions of the light emitting layers 123 where the insulating layer 122 is provided, which is made of an insulating material. Thus, light is emitted from only parts of the light emitting layers 123, positioned in the openings 122z1, 122z2, and 122z3 where no insulating layer 122 is provided. These minimum rectangular regions including the openings 122z1, 122z2, and 122z3 are the luminous regions 100a.

In the light emitting layers 123, light is not emitted from parts that are located above the insulating sublayers 122X. These parts are the non-luminous regions 100b. In other words, the non-luminous regions 100b correspond to the insulating sublayers 122X that are projected in plan view.

(6) Electron Transport Layer 124

An electron transport layer 124 is formed on the column banks 522Y and on the light emitting layers 123 in the gaps 522z which are defined by the column banks 522Y. In this example, the electron transport layer 124 extends over parts of the column banks 522Y that are exposed from the light emitting layers 123. The electron transport layer 124 has a function of transporting electrons, which are injected from the counter electrode layer 125, to the light emitting layers 123.

(7) Counter Electrode Layer 125

The counter electrode layer 125 is formed so as to cover the electron transport layer 124. The counter electrode layer 125 is continuous over the entire display panel 10, and may be connected to a bus-bar wiring per pixel or per several pixels (not shown). The counter electrode layer 125 and the pixel electrode layers 119 in pairs sandwich the light emitting layers 123 therebetween to form an energizing path to supply carries to the light emitting layers 123. When functioning as a cathode for example, the counter electrode layer 125 supplies electrons to the light emitting layers 123. The counter electrode layer 125 is formed so as to be along a surface of the electron transport layer 124, and is a common electrode for the light emitting layers 123.

Since the display panel 10 is of the top-emission type, the counter electrode layer 125 is made of a light-transmissive and conductive material. The counter electrode layer 125 is made for example of indium tin oxide (ITO) or indium zinc oxide (IZO). Alternatively, the counter electrode layer 125 may be a thin electrode film made of silver (Ag), aluminum (Al), or the like.

(8) Sealing Layer 126

A sealing layer 126 is formed so as to cover the counter electrode layer 125. The sealing layer 126 is provided in order to suppress degradation of the light emitting layers 123 due to exposure to moisture, air, and so on. The sealing layer 126 is provided for the entire display panel 10 so as to cover an upper surface of the counter electrode layer 125. Since the display panel 10 is of the top-emission type, the sealing layer 126 is made of a light-transmissive material such as silicon nitride and silicon oxynitride.

(9) Bond Layer 127

A bond layer 127 bonds the sealing layer 126 and a CF substrate 131 that is provided above the sealing layer 126 in the Z-axis direction. The CF substrate 131 includes an upper substrate 130 that has a lower main surface in the Z-axis direction on which color filter layers 128 and a light shielding layer 129 are formed. The bond layer 127 bonds a rear panel that is composed of the substrate 100X and the layers ranging from the pixel electrode layers 119 to the sealing layer 126, to the CF substrate 131. The bond layer 127 also has a function of preventing the layers from being exposed to moisture, air, and so on.

Also, when refractive indices of the bond layer 127 and the insulating layer 122 of the display panel 10 are represented by n₁ and n₂, respectively, the relationships represented by Formulas 1 and 2 should preferably be satisfied. Further, when gradient of slopes of the reflectors is represented by θ, the relationships represented by Formulas 3 and 4 should preferably be satisfied.

(10) Upper Substrate 130

The CF substrate 131, which includes the upper substrate 130 on which the color filter layers 128 and the light shielding layer 129 are formed, is bonded onto the bond layer 127. Since the display panel 10 is of the top-emission type, the upper substrate 130 is made of a light-transmissive material such as a cover glass and a transparent resin film. Also, providing the upper substrate 130 for example improves the rigidity of the display panel 10, and prevents moisture, air, and so on from intruding the display panel 10.

(11) Color Filter Layers 128

The color filter layers 128 are formed on the upper substrate 130 so as to correspond in position and color to the luminous regions 100a. The color filter layers 128 are transparent layers that are provided for transmitting visible light of wavelength corresponding to the R, G, and B colors, and have a function of transmitting light emitted from the R, G, and B pixels and correcting chromaticity of the light. In this example, the red color filter layers 128R, the green color filter layers 128G, and the blue color filter layers 128B are respectively formed above the luminous regions 100aR in the red gaps 522zR, the luminous regions 100aG in the green gaps 522zG, and the luminous regions 100aB in the blue gaps 522zB. Specifically, the color filter layers 128 are formed for example through a process of applying an ink containing color filter materials and a solvent to the upper substrate 130, which is made of a cover glass for color filter formation having openings arranged in a matrix in units of pixels.

(12) Light Shielding Layer 129

The light shielding layer 129 is formed on the upper substrate 130 so as to correspond in position to boundaries between the luminous regions 100a in the pixels.

The light shielding layer 129 is a black resin layer that is provided in order to prevent transmission of visible light of wavelength corresponding to the R, G, and B colors. The light shielding layer 129 is made for example of a resin material including black pigment having excellent light absorbing property and light shielding property. The light shielding layer 129 is provided also in order to prevent external light from entering the display panel 10, prevent the internal components from being seen through the upper substrate 130, and suppress reflection of external light thereby to achieve the contrast improvement of the display panel 10, and so on. Note that reflection of external light is a phenomenon caused when external light, which has entered the display panel 10 from above the upper substrate 130, is reflected at the pixel electrode layers 119 and thus is emitted from the upper substrate 130.

Also, the light shielding layer 129 has a function of blocking leakage of light emitted from each of the R, G, and B pixels to an adjacent pixel, thereby to prevent unclear boundaries between the pixels. The light shielding layer 129 further has a function of increasing the color purity of light emitted from the pixels.

The light shielding layer 129 includes the column light shielding sublayers 129Y, which extend in the column direction and are arranged in the row direction, and the row light shielding sublayers 129X, which extend in the row direction and are arranged in the column direction. A lattice shape is formed by the column light shielding sublayers 129Y and the row light shielding sublayers 129X. In the organic EL elements 100, the column light shielding sublayers 129Y are arranged so as to overlap the insulating sublayers 122Y as shown in FIG. 7, and the row light shielding sublayers 129X are arranged so as to overlap the insulating sublayers 122X as shown in FIGS. 5 and 6.

4.3 Materials of Components

The following describes an example of materials of the components shown in FIGS. 5 to 7.

(1) Substrate 100x (TFT Substrate)

The substrate 100x is made of a known material for TFT substrate.

The lower substrate 100p is for example a glass substrate, a quartz substrate, a silicon substrate, a metal substrate made of molybdenum sulfide, copper, zinc, aluminum, stainless, magnesium, iron, nickel, gold, or silver, a semiconductor substrate made of gallium arsenide base or the like, or a plastic substrate.

Either thermoplastic resin or thermosetting resin may be used as a plastic material. The plastic material may be for example a single layer of any one type of the following materials or a laminate of any two or more types of the following materials including polyethylene, polypropylene, polyamide, polyimide (PI), polycarbonate, acrylic resin, polyethylene terephthalate (PET), polybutylene terephthalate, polyacetal, other fluororesin, thermoplastic elastomer such as styrene elastomer, polyolefin elastomer, polyvinyl chloride elastomer, polyurethane elastomer, fluorine rubber elastomer, and chlorinated polyethylene elastomer, epoxy resin, unsaturated polyester resin, silicone resin, polyurethane, or copolymer, blend, polymer alloy or the like mainly including such a material.

The gate electrodes 101 and 102 are made for example of a laminate of copper (Cu) and molybdenum (Mo). Alternatively, other metal material is adoptable.

The gate insulating layer 103 is made for example of any known electrically-insulating material such as silicon dioxide (SiO₂) and silicon nitride (SiNx), regardless of whether the material is organic or inorganic.

The channel layers 104 and 105 are made of oxide semiconductor including at least one of indium (In), gallium (Ga), and zinc (Zn).

The channel protection layer 106 is made for example of silicon oxynitride (SiON), silicon nitride (SiN), or aluminum oxide (AlOx).

The source electrodes 107 and 110 and the drain electrodes 108 and 109 are made for example of a laminate of copper-manganese (CuMn), copper (Cu), and molybdenum (Mo).

The similar material is adoptable for the source lower electrodes 111 and 115 and the drain lower electrodes 112 and 114.

The passivation layers 116 are made for example of silicon dioxide (SiO₂), a combination of silicon nitride (SiN) and silicon oxynitride (SiON), or a combination of silicon oxide (SiO) and silicon oxynitride (SiON).

The connection electrode layers 117 are made for example of a laminate of copper-manganese (CuMn), copper (Cu), and molybdenum (Mo). Alternatively, the material of the connection electrode layers 117 may be appropriately selected from conductive materials.

The interlayer insulating layer 118 is made for example of an organic compound such as polyimide, polyamide, and acrylic resin, and has a film thickness of 2000 nm to 8000 nm for example.

(2) Pixel Electrode Layers 119

The pixel electrode layers 119 are made of a metal material. The display panel 10 relating to the present embodiment, which is of the top-emission type, should preferably have a surface part that is highly light-reflective. In the display panel 10 relating to the present embodiment, the pixel electrode layers 119 each may be a laminate including layers selected from a metal layer, an alloy layer, and a transparent conductive layer. The metal layer is made for example of a metal material including silver (Ag) or aluminum (Al). The alloy layer is made for example of alloy of silver, palladium, and copper (APC), alloy of silver, rubidium, and gold (ARA), alloy of molybdenum and chromium (MoCr), or alloy of nickel and chromium (NiCr). The transparent conductive layer is made for example of indium tin oxide (ITO) or indium zinc oxide (IZO).

(3) Insulating Layer 122

The insulating layer 122 is made of an insulating material. For example, an inorganic material is used such as silicon nitride (SiN) and silicon oxynitride (SiON).

(4) Column Banks 522Y

The column banks 522Y have insulating properties, and are made of an organic material such as resin. Examples of the organic material of the column banks 522Y include acrylic resin, polyimide resin, and novolac phenolic resin. The column banks 522Y should preferably have an organic solvent resistance. Also, the column banks 522Y sometimes undergo an etching process, a baking process, and so on during the manufacturing process, and accordingly should preferably be made of a highly resistant material in order to avoid excessive distortion, transformation, and the like due to such processes. Also, fluorine processing may be performed on surfaces of the column banks 522Y in order to provide the surfaces with water repellency. Alternatively, the column banks 522Y may be made of a material containing fluorine.

(5) Hole Injection Layer 120

The hole injection layer 120 is made for example of oxide of a metal such as silver (Ag), molybdenum (Mo), chromium (Cr), vanadium (V), tungsten (W), nickel (Ni), and iridium (Ir), or a conductive polymer material such as polyethylenedioxythiophene (PEDOT).

In the case where the hole injection layer 120 is made of oxide of transition metal, the hole injection layer 120 has energy levels because oxide of transition metal has oxidation numbers. This facilitates hole injection, and thus reduces driving voltage.

(6) Hole Transport Layer 121

The hole transport layer 121 is made for example of a high-molecular compound such as polyfluorene, polyfluorene derivative, polyallylamine, and polyallylamine derivative.

(7) Light Emitting Layers 123

The light emitting layers 123 have a function of emitting light by excitation resulting from injection and recombination of holes and electrons, as described above. The light emitting layers 123 need to be made of a luminous organic material by a wet printing method.

Specifically, the light emitting layers 123 should preferably be made for example of a fluorescent substance disclosed in Japanese Patent Application Publication No. H05-163488, such as oxinoid compound, perylene compound, coumarin compound, azacoumarin compound, oxazole compound, oxadiazole compound, perinone compound, pyrrolopyrrole compound, naphthalene compound, anthracene compound, fluorene compound, fluoranthene compound, tetracene compound, pyrene compound, coronene compound, quinolone compound and azaquinolone compound, pyrazoline derivative and pyrazolone derivative, rhodamine compound, chrysene compound, phenanthrene compound, cyclopentadiene compound, stilbene compound, diphenylquinone compound, styryl compound, butadiene compound, dicyanomethylenepyran compound, dicyanomethylenethiopyran compound, fluorescein compound, pyrylium compound, thiapyrylium compound, selenapyrylium compound, telluropyrylium compound, aromatic aldadiene compound, oligophenylene compound, thioxanthene compound, cyanine compound, acridine compound, and metal complex of 8-hydroxyquinoline compound, metal complex of 2-bipyridine compound, complex of a Schiff base and group III metal, oxine metal complex, and rare earth complex.

(8) Electron Transport Layer 124

The electron transport layer 124 is made for example of oxydiazole derivative (OXD), triazole derivative (TAZ), or phenanthroline derivative (BCP Bphen).

(9) Counter Electrode Layer 125

The counter electrode layer 125 is made for example of indium tin oxide (ITO) or indium zinc oxide (IZO). Alternatively, the counter electrode layer 125 may be a thin electrode film made of silver (Ag), aluminum (Al), or the like.

(10) Sealing Layer 126

The sealing layer 126 has a function of preventing the organic layers such as the light emitting layers 123 from being exposed to moisture, air, and so on. The sealing layer 126 is made for example of a light-transmissive material such as silicon nitride (SiN) and silicon oxynitride (SiON). Also, a resin sealing layer that is made of a resin material such as acrylic resin and silicone resin may be provided on a layer that is made of a material such as silicon nitride (SiN) and silicon oxynitride (SiON).

Since the display panel 10 relating to the present embodiment is of the top-emission type, the sealing layer 126 needs to be made of a light-transmissive material.

(11) Bond Layer 127

The bond layer 127 is made for example of a resin adhesive. A light-transmissive resin material is adoptable such as acrylic resin, silicone resin, and epoxy resin.

(12) Upper Substrate 130

The upper substrate 130 is made for example of a light-transmissive material such as glass, quartz, and plastic.

(13) Color Filter Layers 128

The color filter layers 128 are made of a known resin material (for example, the color resist manufactured by JSR Corporation) or the like.

(14) Light Shielding Layer 129

The light shielding layer 129 is made mainly of an ultraviolet curable resin, such as an ultraviolet curable acrylic resin, to which black pigment is added. The black pigment is for example carbon black pigment, titanium black pigment, metal oxide pigment, or organic pigment.

5. Manufacturing Method of Display Panel 10

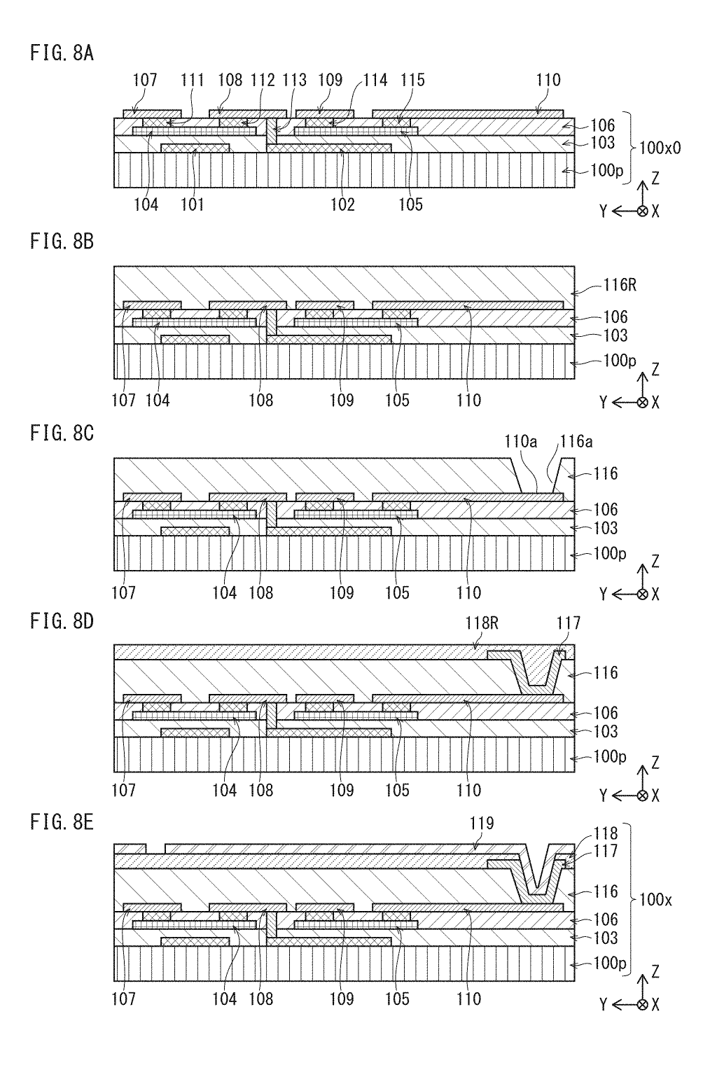

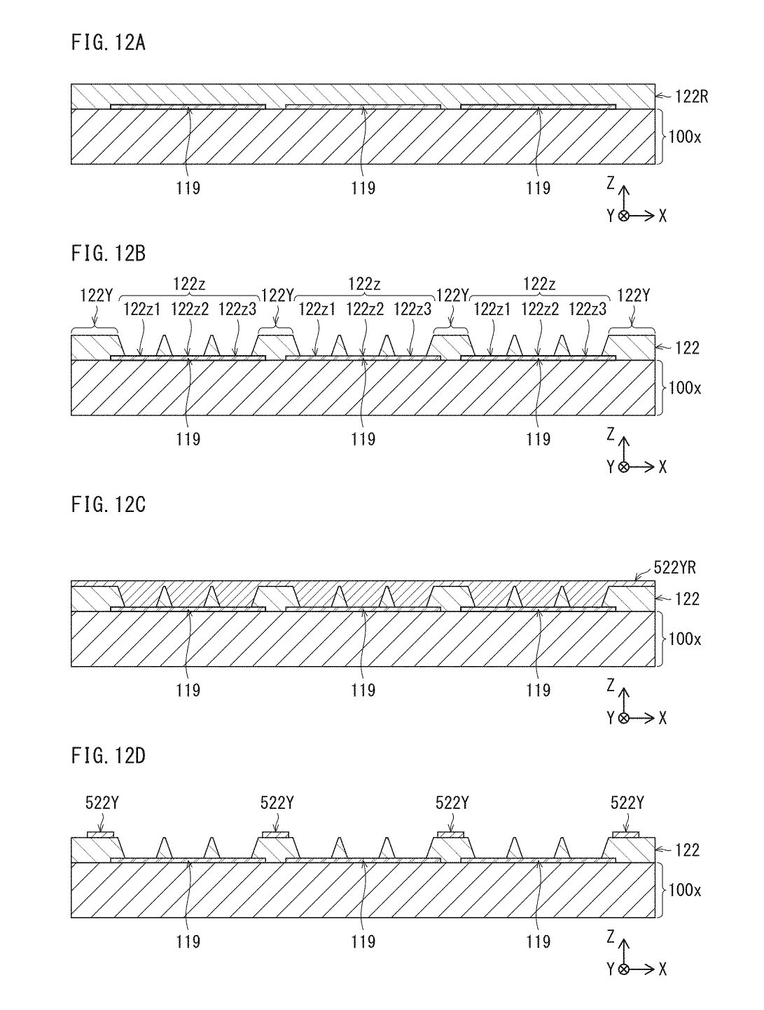

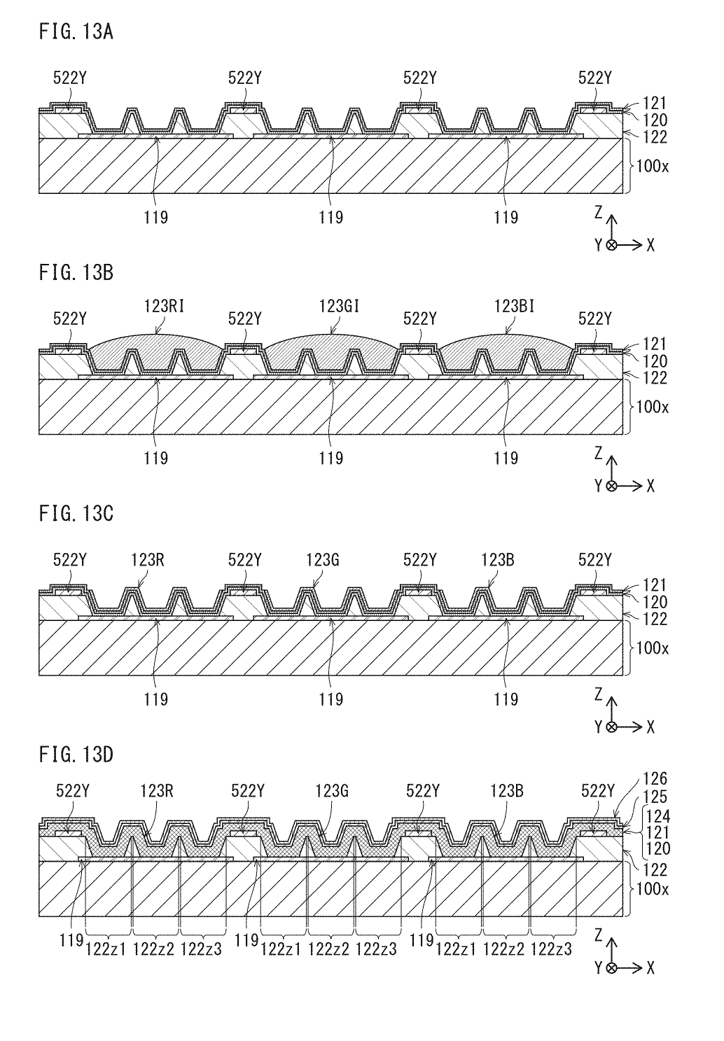

The following describes a manufacturing method of the display panel 10 with reference to the drawings. FIGS. 8A to 8E, FIGS. 9A to 9C, and FIGS. 10A to 10C are schematic cross-sectional views showing the processes of manufacturing the display panel 10, taken along a line at the same position as the line A1-A1 in FIG. 4B. FIGS. 12A to 12D and FIGS. 13A to 13D are schematic cross-sectional views showing the processes of manufacturing the display panel 10, taken along a line at the same position as the line B-B in FIG. 4B.

(1) Formation of Substrate 100x (TFT Substrate)

First, a substrate 100x0 is prepared. The substrate 100x0 has formed thereon components from drain electrodes 101 and 102 to source electrodes 107 and 110 and drain electrodes 108 and 109 (FIG. 8A). The substrate 100x0 is manufactured by a known TFT manufacturing method.

Next, passivation layers 116 are formed for example with a plasma CVD method or a sputtering method so as to cover the source electrodes 107 and 110, the drain electrodes 108 and 109, and a channel protection layer 106 (FIG. 8B).

Next, a contact hole 116a is provided in each of the source electrodes 110 in the passivation layers 116 with a dry etching method (FIG. 8C). The contact hole 116a is provided so as to have a bottom in which a surface 110a of the source electrode 110 is exposed.

Next, connection electrode layers 117 are formed so as to be along inner walls of the contact holes 116a provided in the passivation layers 116. The connection electrode layers 117 have upper portions that are partially on the passivation layers 116. The connection electrode layers 117 are formed by forming a metal film with for example the sputtering method, and then patterning the metal film with a photolithography method and a wet etching method. Furthermore, an interlayer insulating layer 118 is formed by applying an organic material onto the connection electrode layers 117 and the passivation layers 116 so as to cover these layers and planarizing a surface of the applied organic material (FIG. 8D).

(2) Formation of Pixel Electrode Layers 119

Contact holes are provided above the connection electrode layers 117 in the interlayer insulating layer 118. Then, pixel electrode layers 119 are formed in the contact holes (FIG. 8E). The pixel electrode layers 119 are formed by forming a metal film with the sputtering method, a vacuum deposition method, or the like, and then patterning the metal film with the photolithography method and an etching method. Note that the pixel electrode layers 119 are electrically connected with the connection electrode layers 117.

(3) Formation of Insulating Layer 122

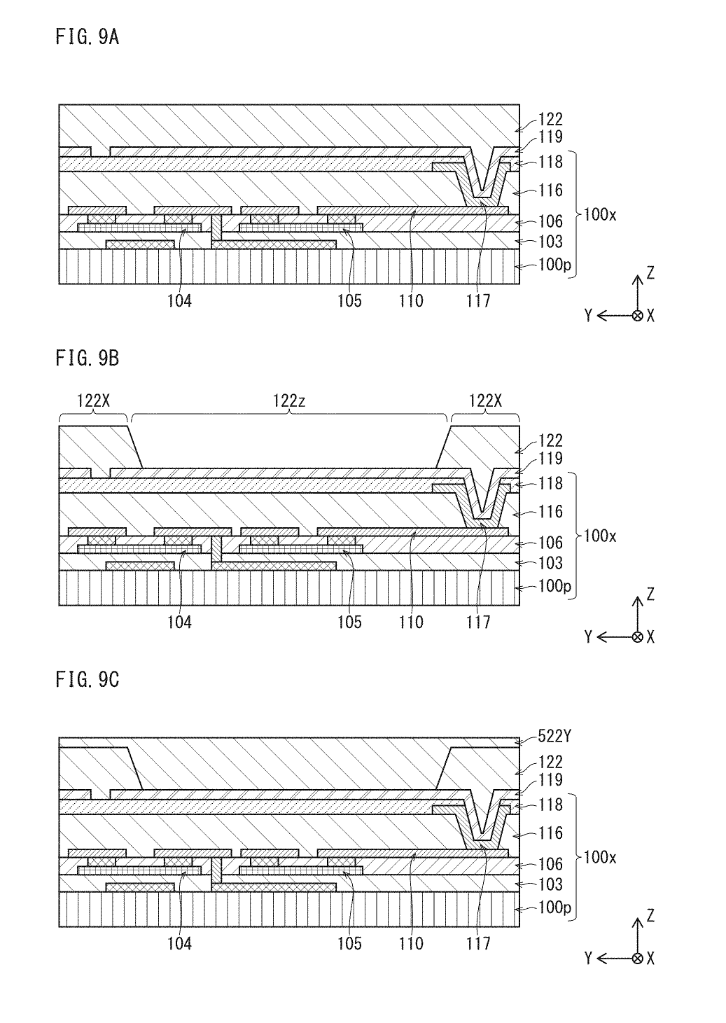

First, a photosensitive resin film 122R metal oxide and metal nitride such as silicon nitride (SiN) and silicon oxynitride (SiON) is formed with a CVD method (FIGS. 9A and 12A). Then, the photosensitive resin film 122R is dried and a solvent thereof is vaporized to a certain degree. Then, a photomask PM having predetermined openings is overlaid above the photosensitive resin film 122R. Ultraviolet irradiation is performed on the photomask PM thereby to transfer patterns of the photomask PM to a photoresist made of photosensitive resin or the like (FIGS. 9B and 12B).

In the present embodiment, the photomask PM is for example a photomask for positive photoresists that includes transmissive parts, through which light transmits, corresponding to the openings 122z. As a result, the photoresist has opening patterns corresponding in shape to the transmissive parts, which correspond to the openings 122z.

Next, development and patterning by a reactive ion etching (RIE) are performed on the photoresist, and as a result the photoresist has patterns of insulating sublayers 122X and 122Y and the openings 122z that constitute an insulating layer 122. (FIGS. 9C and 12C). Parts of the photoresist, which have the patterns of the openings 122z corresponding to the transmissive parts, are removed, and thus result in no insulating layer 122. At this time, the openings 122z have a trapezoidal cross section taken along a plane perpendicular to the longitudinal direction whose width increases toward the upper surface 122Xb of the insulating layer 122, as described above. Meanwhile, parts of the photoresist, which are not exposed, result in the insulating layer 122. In this way, patterning for forming the insulating layer 122 is performed such that the insulating sublayers 122X and 122Y surround regions defining pixels and surfaces of the pixel electrode layers 119 are exposed in bottoms of the openings 122z.

(4) Formation of Column Banks 522Y

Column banks 522Y are formed as follows. First, a film 522YR made of a material of the column banks 522Y such as a photosensitive resin material is formed on the insulating layer 122 with a spin coat method or the like (FIGS. 9C and 12C). Then, the film 522YR is patterned to such that gaps 522z are provided. As a result, the column banks 522Y are formed (FIG. 12D). The gaps 522z are provided by performing exposure through a mask overlaid above the film 522YR and then performing development. The column banks 522Y, extending in the column direction along upper surfaces of the insulating sublayers 122Y, are arranged with the gaps 522z therebetween in the row direction.

(5) Formation of Hole Injection Layer 120 and Hole Transport Layers 121

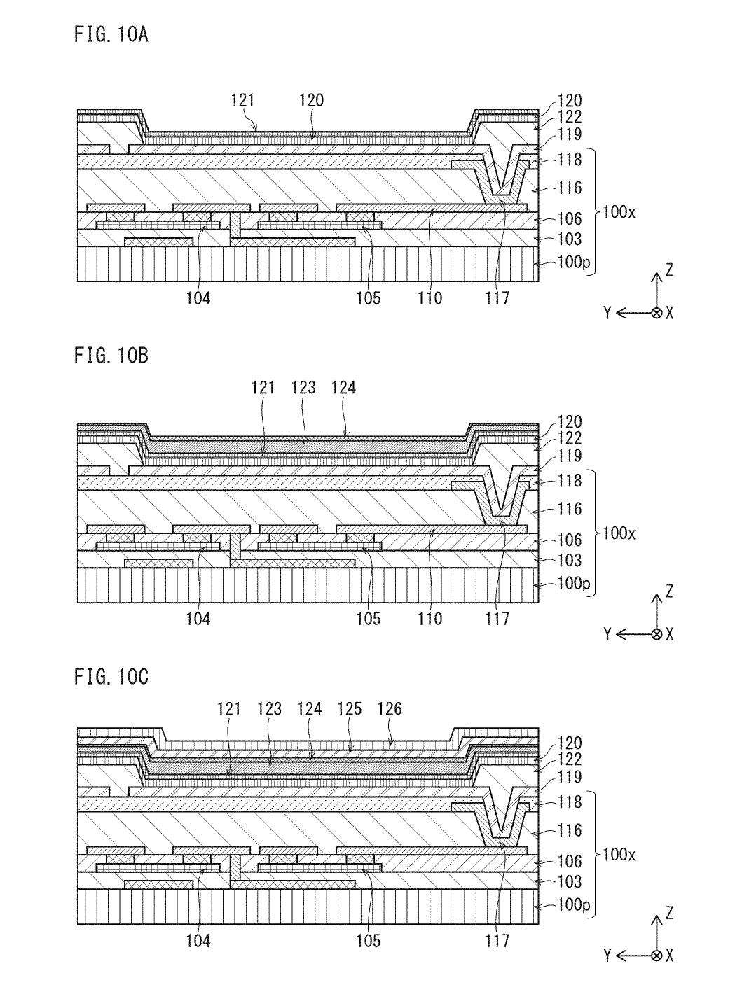

A hole injection layer 120 and hole transport layers 121 are formed above the pixel electrode layers 119, the insulating layer 122, and the column banks 522Y (FIGS. 10A and 13A). The hole injection layer 120 and the hole transport layers 121 may be formed by forming metal oxide films such as tungsten oxide films with the sputtering method, and then patterning the films in units of pixels with the photolithography method and an etching method.

(6) Formation of Light Emitting Layers 123 and Electron Transport Layer 124

In the gaps 522z which are defined by the column banks 522Y, light emitting layers 123 and an electron transport layer 124 are formed on the hole transport layer 121 in this order.

The light emitting layers 123 are formed by applying an ink containing a material of the light emitting layers 123 onto the inside of the gaps 522z, which are defined by the column banks 522Y, with the ink jet method, and then firing the ink.

In formation of the light emitting layers 123, a solution for forming the light emitting layers 123 is first applied with use of an ink discharge device. Specifically, light emitting layers of the R, G, and B colors alternate above the substrate 100x in line in this order in the lateral direction in FIG. 13B. In this process, the gaps 522z, which are regions where subpixels are to be formed, are each filled using the ink jet method with any of inks 123RI, 123GI, and 123BI respectively containing materials of organic light emitting layers of the R, G, and B colors (FIG. 13B). Then, the inks are dried under a reduced pressure and are baked. As a result, the light emitting layers 123R, 123G, and 123B are complete (FIGS. 10B and 13C).

(Method of Applying Solution for Light Emitting Layer Formation)

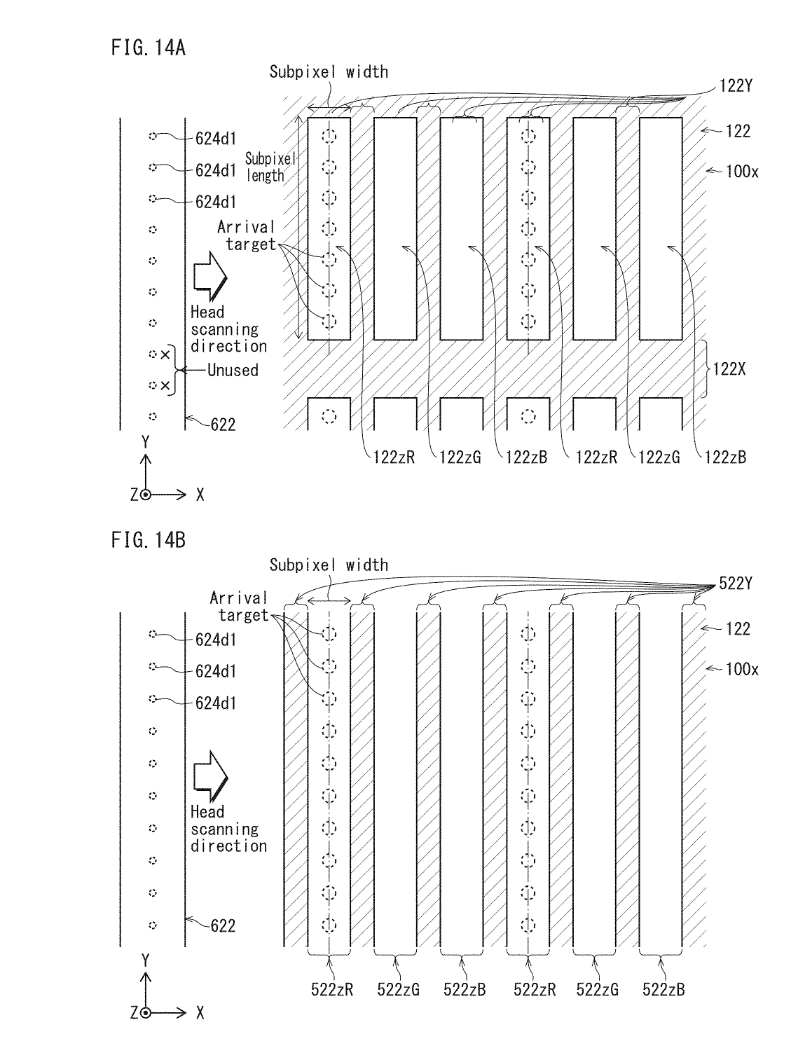

The following describes a process of forming the light emitting layers 123 with the ink jet method for mass production. FIGS. 14A and 14B show a process of applying inks for light emitting layer formation to substrates. Specifically, FIG. 14A shows a case where the inks are applied to regions of a lattice shape defined by the insulating sublayers 122X and 122Y, and FIG. 14B shows a case where the inks are uniformly applied to the gaps 522z between the column banks 522Y.

In formation of the light emitting layers 123, light emitting layers of the R, G, and B colors are formed in the regions defined by the banks arranged in lines, with use of three color inks, namely, the red ink 123RI, the green ink 123GI, and the blue ink 123BI, which are solutions for forming the light emitting layers 123.

For the purpose of simplifying the description, the three color inks are applied in order by the following application method. First, one of the inks is applied over the substrates. Then, another one of the inks is applied over the substrates. Lastly, the last one of the inks is applied over the substrates.

The following describes an application process of one of the three-color inks, namely, the red ink onto substrates as a representative.

### [Ink Application to Regions of Lattice Shape Defined by Insulating Sublayers 122X and 122Y]

The ink is applied to the regions of a lattice shape defined by the insulating sublayers 122X and 122Y.

According to this application method, as shown in FIG. 14A, the substrate 100x is placed such that the longitudinal direction and the width direction of the subpixels 100se respectively coincide with the Y-direction and the X-direction. The ink discharge device performs ink application by, while scanning in the X direction with use of the ink jet head 622, discharging ink from the discharge ports 624d1 toward arrival targets that are set in the regions of a lattice shape which are defined by the insulating sublayers 122X and 122Y. In FIG. 14A, the red subpixels 100se include arrival target positions onto which the red ink is to be applied.

Note that, among the discharge ports 624d1 of the ink jet head 622, only discharge ports 624d1, which pass above regions between each two adjacent insulating sublayers 122X, are used. Meanwhile, discharge ports 624d1 (indicated by sign x in FIG. 14A, which pass above the insulating sublayers 122X, are always unused. According to the example shown in FIG. 14A, seven arrival targets are set in each of the regions of the subpixel, and ink droplets are discharged from seven discharge ports 624d1.

After application of the one of the three color inks over the substrate 100x completes, application of another one of the inks is performed over the same substrate 100x, and lastly application of the last one of the inks is performed above the same substrate 100x. This application process of the three color inks is repeatedly performed for each of the substrates 100x.

Alternatively, the three color inks may be applied in order in the following manner. Specifically, when application of one of the inks above all of the substrates 100x is complete, the application process may be repeatedly performed to apply another one of the inks onto the substrates 100x, and then apply the other ink onto the substrate 100x.

### [Uniform Ink Application to Gaps 522z Between Column Banks 522Y]

The light emitting layers 123 may be located not only above the luminous regions 100a but also above the non-luminous region 100b, which are located between the luminous regions 100a. In other words, the light emitting layers 123 may continuously extend over the luminous regions 100a and the non-luminous region 100b. With this configuration, when forming the light emitting layers 123, an ink applied to the luminous regions 100a can flow in the column direction via an ink applied to the non-luminous regions 100b. This results in uniform film thickness between the pixels in the column direction. Note that the insulating sublayers 122X approximately suppress the ink flow in the non-luminous regions 100b. Thus, a large degree of nonuniformity in film thickness is unlikely to occur in the column direction, and this improves luminance evenness between pixels.

According to this application method, as shown in FIG. 14B, the substrate 100x is placed on a work table of the ink discharge device such that the column banks 522Y are arranged in the Y direction. The ink discharge device performs ink application by, while scanning in the X direction with use of an ink jet head 622 having discharge ports 624d1 arranged in line in the Y direction, discharging ink from the discharge ports 624d1 toward arrival targets that are set in the gaps 522z between the column banks 522Y.

All the discharge ports 624d1 of the ink jet head 622 are used in this application method. This is the difference from the above application method for lattice-shaped regions.

Note that the red ink is applied to one of each three regions that are adjacent to each other in the X-direction.

After application of the one of the three color inks to the substrate 100x is complete, another one of the three color inks is applied to the substrate 100x. Lastly, the last one of the three color inks is applied to the substrate 100x. In this way, the three color inks are applied in order.

(7) Formation of Electron Transport Layer 124, Counter Electrode Layer 125, and Sealing Layer 126

An electron transport layer 124 is formed with the sputtering method or the like. Then, a counter electrode layer 125 and a sealing layer 126 are formed in this order so as to cover the electron transport layer 124 (FIGS. 10C and 13D). The counter electrode layer 125 and the sealing layer 126 are formed with the CVD method, the sputtering method, or the like.

(8) Formation of CF Substrate 131

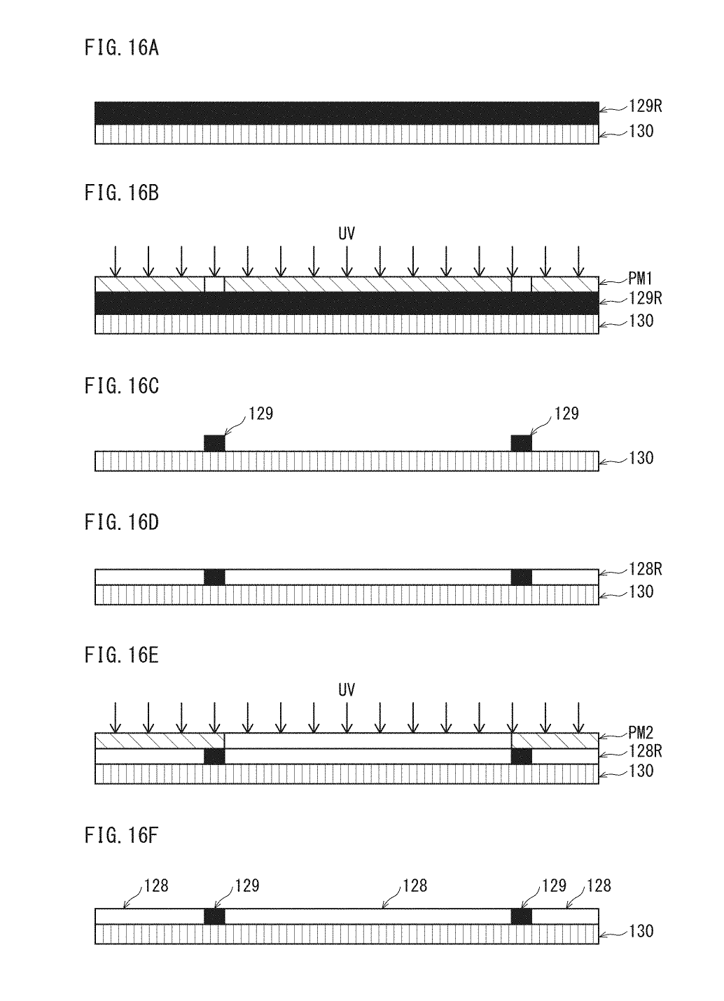

The following exemplifies a process of manufacturing a CF substrate 131 with reference to the figures. FIGS. 16A to 16F are schematic cross-sectional views of the organic EL display panel 10 during manufacture, showing manufacturing of the CF substrate 131.

A light shielding layer paste 129R is prepared by dispersing in a solvent a material of a light shielding layer 129 mainly containing ultraviolet curable resin (for example, ultraviolet curable acrylic resin). The light shielding layer paste 129R is applied onto one of surfaces of a transparent upper substrate 130 (FIG. 16A).

The applied light shielding layer paste 129R is dried and the solvent is vaporized to a certain degree. Then, a pattern mask PM1 having predetermined openings is overlaid above the light shielding layer paste 129R, and ultraviolet irradiation is performed on the pattern mask PM1 (FIG. 16B).

Then, the light shielding layer paste 129R, which has been applied and from which the solvent has been removed, is fired, and development is performed for removing the pattern mask PM1 and uncured parts of the light shielding layer paste 129R. Then, the light shielding layer paste 129R is cured. As a result, the light shielding layer 129 having a rectangular cross-section is complete (FIG. 16C).

Next, a paste 128R is prepared by dispersing in a solvent a material of color filter layers 128 (for example, color filter layers 128G) mainly containing an ultraviolet curable resin component. The paste 128R is applied onto the surface of the upper substrate 130 on which the light shielding layer 129 is formed. The solvent is removed to a certain degree, and then a predetermined pattern mask PM2 is overlaid above the paste 128R and ultraviolet irradiation is performed on the pattern mask PM2 (FIG. 16D).

Then, development is performed for removing the pattern mask PM2 and uncured parts of the paste 128R, and the paste 128R is cured. As a result, the color filter layers 128G are complete (FIG. 16E).

Color filter layers 128R and 128B are also formed by similarly repeating the processes in FIGS. 16D and 16E on color filter materials of the R and B colors. Note that any commercially available color filter products may be used instead of using the paste 128R.

This completes the CF substrate 131.

(9) Bonding of CF Substrate 131 and Rear Panel

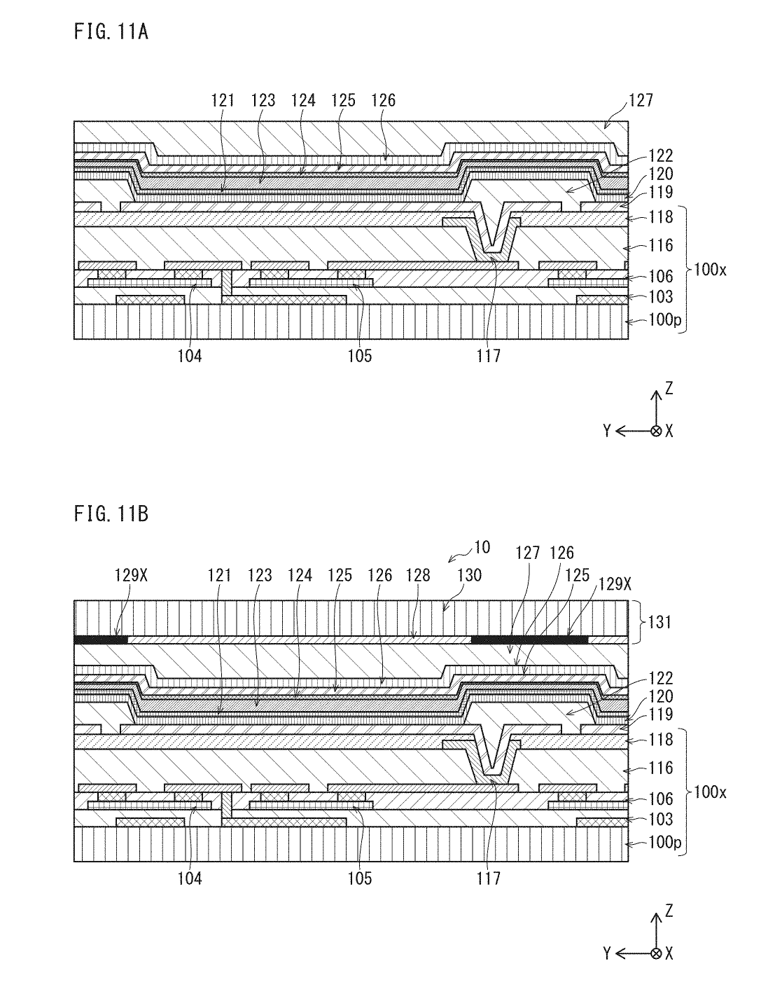

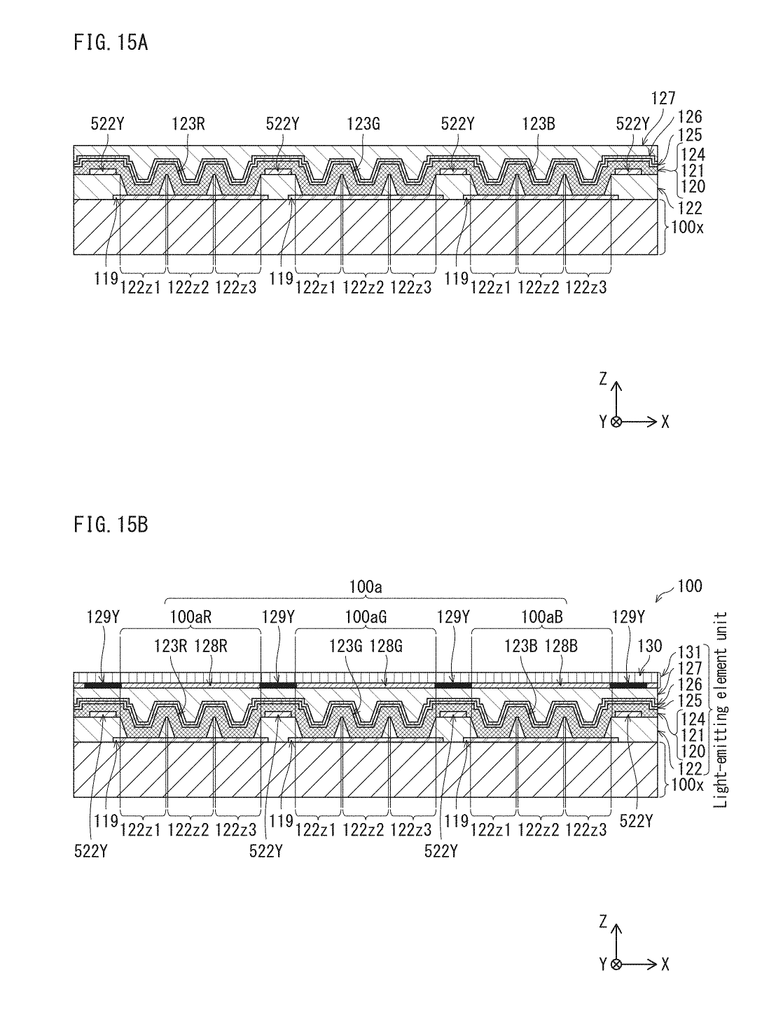

The following describes a bonding process of the CF substrate 131 and a rear panel in manufacturing the display panel 10. FIGS. 11A and 11B are schematic cross-sectional views taken along a line at the same position as the line A1-A1 in FIG. 4B. FIGS. 15A and 15B are schematic cross-sectional views taken along a line at the same position as the line B-B in FIG. 4B.

First, a material of a bond layer 127 mainly containing light-transmissive ultraviolet curable resin is applied onto the rear panel, which is composed of the substrate 100x and the layers ranging from the pixel electrode layers 119 to the sealing layer 126 (FIGS. 11A and 15A). The light-transmissive ultraviolet curable resin is for example acrylic resin, silicone resin, or epoxy resin.

Subsequently, ultraviolet irradiation is performed on the applied material such that the CF substrate 131 and the rear panel are bonded to each other while positions relative to each other are maintained. At this time, intrusion of gas therebetween needs to be prevented. Then, the CF substrate 131 and the rear panel are fired. This completes a sealing process. In this way, the display panel 10 is complete (FIGS. 11B and 15B).

6. Effect of Display Panel 10

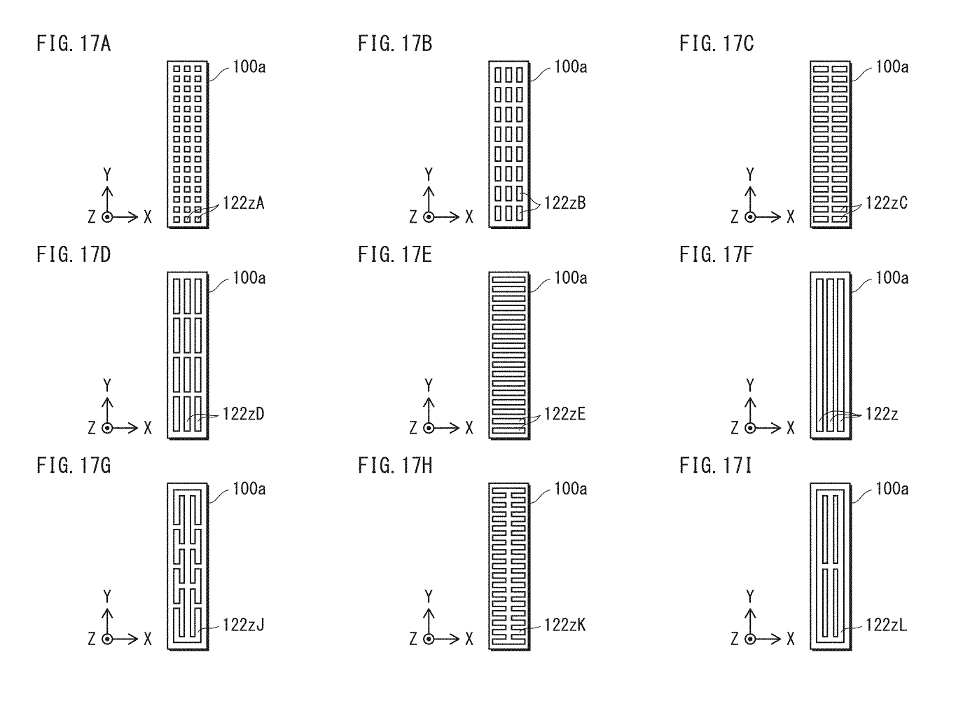

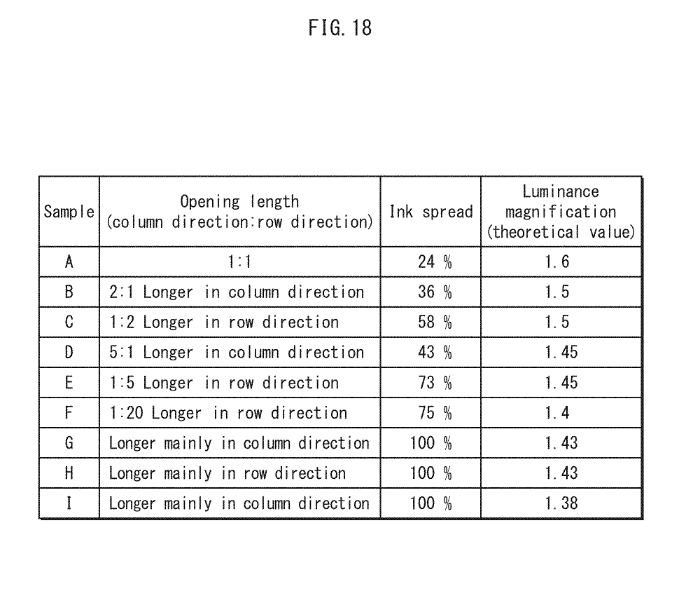

With reference to FIGS. 17A to 17I and 18, a comparative description is given on the reflectors relating to the present embodiment with conventional reflectors in terms of light extraction efficiency and ink spread.

(1) Opening Shape

FIG. 17F is a plan view of a subpixel 100se relating to the present embodiment, where the insulating layer 122 has a shape such as shown in FIG. 19A (hereinafter referred to as Sample F). Compared with this, FIG. 17A is a plan view of a subpixel 100seA with the conventional reflectors (hereinafter referred to as Sample A). In the reflectors of Sample A, an insulating layer 122A has a plurality of truncated square pyramid openings 122zA. Specifically, 48 truncated square pyramid openings 122zA, which are squares in plan view, are provided such that three rows of openings 122zA are arranged in regular intervals in the X-direction and 16 rows of openings 122zA are arranged in regular intervals in the Y-direction. A region including the 48 openings 122zA constitutes a luminous region 100a. In openings 122z of Sample F, the width in the column direction is 20 times the width in the row direction (20:1). Compared with this, in the openings 122zA of Sample A, the width in the column direction is equal to the width in the row direction (1:1). Samples A and F are equal to each other in terms of subpixel shape. Accordingly, the openings 122zA of Sample A and the openings of Sample F are substantially equal to each other in terms of width in the row direction.

(2) Light Extraction Efficiency by Reflectors

It is true that the light extraction efficiency of Sample F is low compared with that of Sample A, but its ratio to that of Sample A is only approximate 1.4/1.6. Accordingly, the light extraction efficiency of Sample F is not low enough to greatly damage effects of the reflectors. This seems to be because of the following reason. The light extraction efficiency by the reflectors increases with an increase in area of slopes 122t surrounding the openings 122z functioning as the reflective structure. Due to this, the light extraction efficiency increases with a decrease in difference between the width in the column direction and the width in the row direction of the openings. Accordingly, Sample A functions as preferable reflectors and thus exhibits a high light extraction efficiency. Compared with this, Sample F has bars, which extend in the row direction in the insulating layer 122, only at both ends of the subpixel 100se in the column direction. Accordingly, Sample F has small-area slopes extending in the row direction and thus exhibits a lower light extraction efficiency than Sample A. On the other hand, Sample F is larger than Sample A both in terms of area of the luminous region 100a in the column direction and area of slopes extending in the column direction. This seems to be the reason why the light extraction efficiency of Sample F is not impaired greatly.

(3) Ink Spread

Regarding the ink spread, the inventors performed a test of forming functional layers using inks of the same amount, and made a comparison of the ink spread rate based on the area of the functional layers. FIG. 18 shows results of the test. While Sample A exhibits an ink spread rate of 24%, Sample F exhibits an ink spread rate of 75%, which is drastically higher than Sample A. This seems to be because of the following reasons. In Sample A, the number and the area of the bars between the openings 122zA are both large, and this hinders the flow of the ink. Also, since the area of the openings 122zA is small, capillarity due to the surface tension of the ink causes the ink to remain inside the openings 122zA. The remaining ink cannot easily flow into adjacent openings. This seems to be the reason why the spread of the ink over the subpixel is difficult in Sample A. In Sample F compared with this, the openings 122z have therebetween no bar that hinders the flow of the ink in the column direction, and thus the ink easily flows in the column direction. Further, since the openings 122z are elongated and extend in the column direction, the ink in the openings 122z spontaneously flows in the column direction, and thus the ink flow cannot be hindered by the capillarity. This seems to be the reason why Sample F exhibits an ink spread rate, which is drastically higher than Sample A.

(4) Summary

In view of the above test results, Sample F is somewhat lower than Sample A in terms of light extraction efficiency, but is higher than Sample A in terms of ink spread. In other words, the configuration of the subpixels 100se relating to the embodiment exhibits a great effect of uniformizing the film thickness of the application-type functional layers to suppress an insufficient ink spread. According to the embodiment, thus, it is possible to achieve organic EL display panels including application-type functional layers where an improved light extraction efficiency is exhibited and increased efficiency and panel service life are exhibited owing to a uniform film thickness of the functional layers.

7. Other Opening Shapes

Sample F relating to the embodiment has elongated openings 122z1, 122z2, and 122z3 of the insulating layer 122, which extend in the column direction (the Y-direction in FIG. 3). The inventors further considered other shapes of the openings.

Note that each of other samples to the embodiment described below is equal to Sample F in terms of conditions except the shape of the openings of the insulating layer 122. Further, each of the other samples relating to the embodiment is also equal to Sample F or Sample A in terms of material and amount of ink for the spread test.

(1) Openings Extending in Column Direction

Sample F has the elongated openings 122z, which extend in the column direction (the Y-direction in FIG. 3). Based on this, the inventors considered openings that extend in the column direction and have different lengths in the column direction. In Sample F, the width of the openings 122z in the column direction is 20 times the width of the openings 122z in the row direction. Based on this, the inventors further considered Samples D (FIG. 17D) and Sample B (FIG. 17B). In Sample D, the width of openings 122zD in the column direction is five times the width of the openings 122zD in the row direction. In Sample B, the width of openings 122zB in the column direction is twice the width of the openings 122zB in the row direction. Note that the openings 122z, 122zB, and 122zD have the substantially equal width in the row direction.

As shown in FIG. 18, Sample D is lower in ink spread than Sample F, and Sample B is lower in ink spread than Sample D. Meanwhile, even Sample B is higher in ink spread than Sample A. These test results prove that the ink spread increases with an increase in width of the openings in the column direction that is longer than the width of the openings in the row direction, in other words, the ink spread increases as the openings extends longer in the column direction. This seems to be because, as described above, as the openings extends longer in the column direction, the number of bars hindering the ink flow reduces and also the ink is promoted to spontaneously flow in the longitudinal direction, and thus the ink easily flows. Meanwhile, these test results prove that the light extraction efficiency decreases as the openings extends longer in the column direction. This seems to be because, as described above, as the openings extends longer in the column direction, the area of the slopes extending in the row direction reduces.

(2) Openings Extending in Row Direction

Also, the inventors considered openings that extend in the row direction to verify whether the extending direction of the openings influences the ink spread and the light extraction efficiency. Then, the inventors considered Sample E (FIG. 17E) relative to Sample D and Sample C (FIG. 17C) relative to Sample B. In Sample E, the width of openings 122zE in the row direction is five times the width of the openings 122zE in the column direction. In Sample C, the width of openings 122zC in the row direction is twice the width of the openings 122zC in the column direction. Note that the openings 122zC and 122zE have the substantially equal width in the column direction.

As shown in FIG. 18, Sample C is lower in ink spread than Sample E. Meanwhile, Sample E is higher in ink spread than Sample D, and Sample C is higher in ink spread than Sample B. These test results prove that the ink spread increases as a ratio of the width in the longitudinal direction to the width in the short direction of the elongated openings increases, regardless of the extending direction of the openings. The reason why Samples E and C, whose openings extend in the row direction, are respectively higher in ink spread than Samples D and B, whose openings extend in the column direction, seems to be the subpixels 100se extending in the column direction. In other words, it seems that because of the subpixels 100se extending in the column direction, an insufficient ink flow in the row direction is more likely than an insufficient ink flow in the column direction to increase the area of insufficient ink spread regions. Thus, it seems that the openings and the bars of the pixel inner insulating layer which extend in the column direction deteriorate the ink flow in the row direction and the ink spread than the openings and the bars which extend in the row direction.

(3) Openings Constituted from Elongated Opening Pieces

The inventors further considered the following cases other than the case where openings are constituted from elongated opening pieces extending in the same direction.

In Sample G shown in FIG. 17G, an opening 122zJ is constituted from elongated opening pieces extending in the column direction and elongated opening pieces extending in the row direction. For details, the opening 122zJ is constituted from nine elongated opening pieces extending in the column direction and four elongated opening pieces extending in the row direction. A specific description is given below. First, a subpixel 100se is divided into three regions in the row direction. One elongated opening piece extending in the column direction is provided in the center region, and four elongated opening pieces extending in the column direction are provided in each of the both side regions. Furthermore, four elongated opening pieces extending in the row direction are provided. Specifically, one elongated opening piece extending in the row direction is provided in each of both ends of the subpixel 100se in the column direction. One elongated opening piece extending in the row direction is provided in each of two central regions among four regions from which the subpixel 100se is divided in the column direction. As a result, the opening 122zJ is continuous. That is, all of the elongated opening pieces, which constitute the opening 122zJ, are each connected with at least another one of the elongated opening pieces.

Also, in Sample H shown in FIG. 17H, an opening 122zK is constituted from one elongated opening piece extending in the column direction and the openings 122zE of Sample E. As a result, the opening 122zK is continuous. That is, all of the elongated opening piece and the elongated openings 122zE, which constitute the opening 122zK, are each connected with at least another one of the elongated opening pieces and the elongated openings 122zE.

Furthermore, in Sample I shown in FIG. 17I, an opening 122zL is constituted from three elongated openings extending in the row direction and the openings 122z of Sample F. As a result, the opening 122zL is continuous. That is, all of the elongated opening pieces and the elongated openings 122z, which constitute the opening 122zL, are each connected with at least another one of the elongated opening pieces and the elongated openings 122z.

As shown in FIG. 18, Samples G, H, and I are high in terms of ink spread. These test results prove that the ink spread is also improved by even the openings which are constituted from elongated opening pieces. Note that the reason for a high ink spread in Samples G, H, and I is the continuity of the opening in the subpixel 100se. Due to this, in the case where an insufficient ink spread occurs locally in the subpixel 100se, the ink flows along the periphery of the opening and thus the ink spreads in an extremely uniform manner. According to this configuration, thus, in manufacturing of the light emitting layers 123, the ink only needs to be dropped in at least one part in a region that is to be a luminous region 100a of each subpixel 100se. Even in the case where the discharge interval by the discharge ports 624d1 is longer than the width in the longitudinal direction of each of the elongated opening pieces constituting the opening, it is possible to manufacture the light emitting layers 123 having an appropriate film thickness.

8. Summary of Effect of Display Panel 10

As described above, the inventors proved that the ink spread is improved by the openings of the pixel inner insulating layer which are constituted from elongated opening pieces. Here, the description that “openings of the pixel inner insulating layer are constituted from elongated opening pieces” means that two or more elongated openings 122z are provided in the insulating layer 122 of one subpixel 100se so as to be spaced from each other or so as to partially overlap each other. According to this configuration of the openings, the ink spread is improved in formation of application-type functional layers, and as a result the functional layers have a uniform film thickness. This contributes to luminous efficiency improvement and panel service life prolonging. Further, the configuration of the openings exhibits the effects of the reflectors, and thus contributes to luminance improvement.

### Other Modifications

In the above embodiment, the display panel 10 is described. However, the present disclosure is not limited to the above embodiment except the essential characteristic compositional elements thereof. For example, the present disclosure also includes an embodiment obtained through various types of modifications which could be conceived of by one skilled in the art to the above embodiment, an embodiment obtained through any combination of the compositional elements and the functions in the above embodiment without departing from the spirit of the present disclosure, and so on. The following describes modifications of the display panel 10 as examples of such an embodiment.

(1) In the display panel 10 relating to the embodiment, the CF substrate 131, on which the light shielding sublayers 129X and 129Y are provided, is bonded onto the rear panel, which is composed of the substrate 100X and the layers ranging from the pixel electrode layers 119 to the sealing layer 126. Alternatively, in the exemplified display panel 10, the light shielding sublayers 129X and 129Y may be directly provided on the rear panel.

(2) In the display panel 10, the light emitting layers 123 are continuous in the column direction above the row banks. Alternatively, the light emitting layers 123 may not be continuous for the entire pixels above the row banks.

(3) In the display panel 10, the light emitting layers 123 of the subpixels 100se, which are arranged in the gaps 522z between the column banks 522Y adjacent to each other in the row direction, each emit light of a color different from adjacent one. Meanwhile, the light emitting layers 123 of the subpixels 100se, which are arranged in the gaps 522z between the insulating sublayers 122X adjacent to each other in the column direction, emit light of the same color. Alternatively, the light emitting layers 123 of the subpixels 100se, which are adjacent to each other in the row direction, may emit light of the same color, and the light emitting layers 123 of the subpixels 100se, which are adjacent to each other in the column direction, each may emit light of a color different from adjacent one. Further alternatively, the light emitting layers 123 of the subpixels 100se, which are adjacent to each other in the row direction, each may emit light of a color different from adjacent one, and the light emitting layers 123 of the subpixels 100se, which are adjacent to each other in the column direction, each may emit light of a color different from adjacent one.

(4) In the display panel 10, the CF substrate 131 is bonded via the bond layer 127 onto the rear panel, which is composed of the substrate 100X and the layers ranging from the pixel electrode layers 119 to the sealing layer 126. In addition, a photo spacer may be inserted between the CF substrate 131 and the rear panel.

(5) In the display panels relating to the embodiment and the modifications, when the refractive indices of the bond layer 127 and the insulating layer 122 of the display panel 10 are represented by n₁ and n₂, respectively, the relationships represented by Formulas 1 and 2 are satisfied. Further, when the gradient of the slopes of the reflectors is represented by θ, the relationships represented by Formulas 3 and 4 are satisfied. Alternatively, the four following relationships may be satisfied. Specifically, among the layers ranging from the insulating layer 122 to the bond layer 127, when a refractive index of a layer provided near the color filter layers 128 is represented by and n₃ and a refractive index of a layer provided near the pixel electrode layers 119 is represented by n₄, the following relationships may be satisfied: 1.1≤n₃≤1.8 (Formula 8); and |n₃−n₄|≥0.20 (Formula 9). Also, when the gradient of the slopes of the reflectors is represented by θ, the following relationships may be satisfied: n₄<n₃ (Formula 10); and 75.2−54(n₃−n₄)≤θ≤81.0−20(n₃−n₄) (Formula 11).

(6) Others

The display panel 10 relating to the above embodiment includes the subpixels 100se of the three colors of red, green, and blue. However, the present disclosure is not limited to this. For example, light emitting layers of a single color and subpixels of the single color may be employed. Alternatively, light emitting layers of four colors of red, green, blue, and yellow and subpixels of the four colors may be employed. Further alternatively, subpixels of a single color may have light emitting layers of two or more colors. For example, subpixels emitting yellow light may have red light emitting layers and green light emitting layers. Yet alternatively, subpixels that are larger in number of color types than light emitting layers may be achieved by combining the light emitting layers with color filters. For example, red, green, and blue pixels may be achieved respectively by combining white light emitting layers with red, green, and blue light-transmissive filters. Furthermore, the unit pixel 100e does not necessarily need to be composed of subpixels 100se. For example, the unit pixel 100e may be composed of a single subpixel 100se and have the same configuration as the subpixels 100e relating to the embodiment.

Also, the unit pixels 100e and the subpixels 100se, which constitute the unit pixels 100e, are arranged in a matrix in the above embodiment. However, the present disclosure is not limited to this. In the case for example where an interval of the pixel region is one pitch, the pixel region may be shifted in the column direction by half pitch between adjacent gaps.

Also, the display panel 10 includes the pixel electrode layers 119 each of which are provided between every two of all the gaps 522z. However, the present disclosure is not limited to this. For example, some of the gaps 522z may not have the pixel electrode layer 119 therebetween in order to form a bus bar or the like.

Moreover, the display panel 10 includes the color filter layers 128 that are provided above the gaps 522z corresponding to the subpixels 100se of the R, G, and B colors. Alternatively, the exemplified display panel 10 may have a configuration in which the color filter layers 128 are not provided above the gaps 522z.

Also, in the above embodiment, the hole injection layer 120, the hole transport layer 121, the light emitting layers 123, and the electron transport layer 124 are provided between each of the pixel electrode layers 119 and the counter electrode layer 125. However, the present disclosure is not limited to this. For example, only the light emitting layers 123 may be provided between each of the pixel electrode layers 119 and the counter electrode layer 125, without providing the hole injection layer 120, the hole transport layer 121, and the electron transport layer 124. Alternatively, a hole injection layer, a hole transport layer, an electron transport layer, an electron injection layer, and so on may be included, or some or all of these layers may be simultaneously included, for example. Moreover, all of these layers do not need to be made of organic compound, and alternatively some of the layers may be made of inorganic substance or the like. Furthermore, the hole injection layer 120, the hole transport layer 121, and the electron transport layer 124 may be formed using a dry deposition method such as the vacuum deposition method, an electron beam deposition method, the sputtering method, a reactive sputtering method, an ion plating method, and a chemical vapor deposition method. Also, in the case where the hole injection layer 120 and the hole transport layer 121 are formed using the dry deposition method, the pixel electrode layers 119, the hole injection layer 120, the hole transport layer 121, the insulating layer 122, and the light emitting layers 123 may be layered in this order.

Also, in the above embodiment, the light emitting layers 123 are formed using a wet deposition method such as the printing method, the spin coating method, and the ink jet method. However, the present disclosure is not limited to this. For example, the dry deposition method may be used such as the vacuum deposition method, the electron beam deposition method, the sputtering method, the reactive sputtering method, the ion plating method, and the chemical vapor deposition method. Moreover, a known material may be appropriately adopted for the materials of the components.

Also, in the above embodiment, the pixel electrode layers 119 as anodes are provided in the lower part of the organic EL element unit so as to be connected with the source electrodes of the TFTs. Alternatively, the counter electrode layer and the anodes may be provided respectively in the lower part and the upper part of the organic EL element unit. In this case, the cathode that is provided in the lower part is connected with the drain electrodes of the TFTs.

Also, the two transistors Tr₁ and Tr₂ are provided for each subpixel 100se in the above embodiment. However, the present disclosure is not limited to this. For example, one transistor may be provided for each subpixel, or three or more transistors may be provided for each subpixel.

Furthermore, an EL display panel of the top-emission type is exemplified in the above embodiment. However, the present disclosure is not limited to this. For example, the present disclosure may be applied to a display panel of a bottom-emission type. In this case, the configurations of the components may be appropriately modified.

Also, in the above embodiment, the display panel 10 is an active-matrix display panel. However, the present disclosure is not limited to this. For example, the display panel 10 may be a passive-matrix display panel. Specifically, pairs of a linear electrode, which is parallel to the column direction, and a linear electrode, which is parallel to the row direction, may be provided such that each pair of the electrodes sandwich the light emitting layer 123 therebetween. In this case, the configurations of the components may be appropriately modified. Although the substrate 100x in the above embodiment includes the TFT layer, the substrate 100x does not necessarily need to include the TFT layer as seen in the above example of the passive-matrix display panel.

<<Supplements>>

The embodiment described above shows a specific preferred example of the present disclosure. The numerical values, the shapes, the materials, the components, the arrangement and connection status of the components, the processes, the order of the processes, and so on described in the above embodiment are just examples, and do not intend to limit the present disclosure. Also, processes among the components in the embodiment, which are not described in the independent claims representing the most generic concept of the present disclosure, are explained as arbitrary components of a more preferred embodiment.

Furthermore, the order of performing the above processes is exemplification for specifically describing the present disclosure, and the processes may be performed in an order different from the above one. Moreover, part of the above processes may be performed simultaneously (in parallel) with other process.

Also, the components shown in the figures in the above embodiment are not necessarily drawn to scale for easy understanding of the present disclosure. Furthermore, the present disclosure is not limited by the description of the above embodiment, and may be appropriately modified without departing from the scope of the present disclosure.

Moreover, at least part of the functions of the above embodiment and modifications may be combined with each other.

Furthermore, the present disclosure also includes embodiments obtained through various types of modifications that could be conceived of by one skilled in the art to the above embodiment.

### INDUSTRIAL APPLICABILITY

The organic EL display panel and the organic EL display device relating to the present disclosure are broadly utilizable to devices such as television sets, personal computers, and mobile phones, or other various types of electrical devices having display panels.

### REFERENCE SIGNS LIST

1 Organic EL display device
10 Organic EL display panel
100 Organic EL element
100e Unit pixel
100se Subpixel
100a Luminous region
100b Non-luminous region
100x Substrate (TFT substrate)
100p Lower substrate
101, 102 Gate electrode
103 Gate insulating layer
104, 105 Channel layer
106 Channel protection layer
107, 110 Source electrode
108, 109 Drain electrode
111 Source lower electrode
112 Drain lower electrode
113 Contact plug
116 Passivation layer
117 Connection electrode layer
118 Interlayer insulating layer
119 Pixel electrode layer
119a1, 119a2, 119a3, 119a4 Outer edge
119b Contact region (contact window)
119c Connection concave part
120 Hole injection layer
121 Hole transport layer
122, 122X, 122Y Insulating layer
122z Opening
122w Bar
123 Light emitting layer
124 Electron transport layer
125 Counter electrode layer
126 Sealing layer
127 Bond layer
128 Color filter layer
129 Light shielding layer
129X Row light shielding sublayer
129Y Column light shielding sublayer
130 Upper substrate
131 CF substrate
522Y Column bank
522z Gap

1. An organic electroluminescence (EL) display panel including pixels arranged in a matrix of rows and columns, wherein
the pixels each include a lower layer, an inner insulating layer, an application-type functional layer, and an upper electrode that are layered in this order, the lower layer including a lower electrode, the functional layer including a light-emitting layer,
the inner insulating layer has one or more openings in which the lower layer is exposed,
the openings each have a width increasing toward the upper electrode and have a slope toward a periphery of the pixel, and
in plan view, the openings are constituted from a plurality of elongated opening pieces.

2. The organic EL display panel of claim 1, wherein
in plan view, the plurality of opening pieces include opening pieces that are arranged in a row direction and extend in a column direction.

3. The organic EL display panel of claim 2, wherein
in plan view, the plurality of opening pieces further include opening pieces that are arranged in the column direction and extend in the column direction.

4. The organic EL display panel of claim 1, wherein
in plan view, the plurality of opening pieces include opening pieces that are arranged in a column direction and extend in a row direction.

5. The organic EL display panel of claim 4, wherein
in plan view, the plurality of opening pieces further include opening pieces that are arranged in the row direction and extend in the row direction.

6. The organic EL display panel of claim 1, wherein
in plan view, the plurality of opening pieces include opening pieces that extend in a column direction and one or more opening pieces that extend in a row direction, and
in plan view, the opening pieces extending in the column direction each partially overlap with one or more of the opening pieces extending in the row direction.

7. The organic EL display panel of claim 1, wherein
in plan view, the plurality of opening pieces include opening pieces that extend in a row direction and one or more opening pieces that extend in a column direction, and
in plan view, the opening pieces extending in the row direction each partially overlap with one or more of the opening pieces extending in the column direction.

8. An organic electroluminescence (EL) display device comprising an organic EL display panel, wherein
the organic EL display panel includes pixels arranged in a matrix of rows and columns,
the pixels each include a lower layer, an inner insulating layer, an application-type functional layer, and an upper electrode that are layered in this order, the lower layer including a lower electrode, the functional layer including a light-emitting layer,
the inner insulating layer has one or more openings in which the lower layer is exposed,
the openings each have a width increasing toward the upper electrode and have a slope toward a periphery of the pixel, and
in plan view, the openings are constituted from a plurality of elongated opening pieces.

9. A method of manufacturing an organic electroluminescence (EL) display panel including pixels arranged in a matrix of rows and columns, the method comprising:
preparing a substrate;
forming pixel electrode layers on the substrate in the matrix, the pixel electrode layers being made of a light-reflective material;
forming an insulating layer above the substrate and the pixel electrode layers;
providing one or more openings for each of the pixels in the insulating layer by a photolithography method, the pixel electrode layers being exposed in the openings, the openings each having a width increasing toward the upper electrode and having a slope toward a periphery of the pixel, and the openings being constituted from a plurality of elongated opening pieces in plan view;
forming, at least in the openings of the pixels, functional layers including light emitting layers by applying an ink above the pixel electrode layers and drying the ink, the ink containing a material of the light emitting layers; and
forming a light-transmissive counter electrode layer above the functional layers.
